(19) United States
(12) Patent Application Publication
(10) Pub. No.: US 2026/0247529 A1
(43) Pub. Date: Aug. 20, 2026

(54) FILM, LAMINATED FILM, LAMINATED PLATE, PRINTED WIRING BOARD, ANTENNA SUBSTRATE, ANTENNA MODULE, METAMATERIAL, AND ELECTROMAGNETIC WAVE ABSORBING FILM

(71) Applicant: FUJIFILM Corporation, Tokyo (JP)

(72) Inventors: Yasuyuki SASADA, Kanagawa (JP); Masaki KOHAMA, Kanagawa (JP); Shohei YAMAZAKI, Kanagawa (JP); Makoto UCHIMURA, Kanagawa (JP); Yukito SAITOH, Kanagawa (JP)

(73) Assignee: FUJIFILM Corporation, Tokyo (JP)

(21) Appl. No.: 19/452,373

(22) Filed: Jan. 18, 2026

Related U.S. Application Data
(63) Continuation of application No. PCT/JP2024/025831, filed on Jul. 18, 2024.

(30) Foreign Application Priority Data
Jul. 20, 2023 (JP) 2023-118688
Oct. 31, 2023 (JP) 2023-187213
Dec. 8, 2023 (JP) 2023-207955
Feb. 28, 2024 (JP) 2024-029091

(51) Int. Cl. H05K 1/03; H01Q 1/38

(52) U.S. Cl. CPC H05K 1/036; H01Q 1/38; H05K 2201/0215; H05K 2201/0242; H05K 2201/0263; H05K 2201/10098

(57) ABSTRACT

A film contains a filler, and a resin, the filler is at least one selected from the group consisting of an inorganic filler and an organic filler, and a ratio (Do/Di) of a density (Do) of particles of the filler in a thickness direction to a density (Di) of particles of the filler in an in-plane direction is 0.5 or more.

### CROSS-REFERENCE TO RELATED APPLICATION

This application is a Continuation of International Application No. PCT/JP2024/025831 filed Jul. 18, 2024, which claims priority to Japanese Patent Application No. 2023-118688, filed Jul. 20, 2023, Japanese Patent Application No. 2023-187213, filed Oct. 31, 2023, Japanese Patent Application No. 2023-207955, filed Dec. 8, 2023, and 2024-029091, filed Feb. 28, 2024. Each of the above applications is hereby expressly incorporated by reference, in its entirety, into the present application.

### BACKGROUND OF THE INVENTION

### 1. Field of the Invention

The present disclosure relates to a film and a laminated plate. In addition, the present disclosure relates to electronic components such as a printed wiring board, an antenna substrate, and a high-frequency antenna using the film or the laminated plate, and a metamaterial that acts on a high-frequency signal.

### 2. Description of the Related Art

In recent years, communication equipment has been developed to be faster, and a frequency used for communication tends to be very high. In addition, there is an increasing demand for electronic components used in communication, such as size reduction and high-density mounting. As a member constituting such an electronic component, a high-dielectric material is suitably used, and a composition obtained by mixing an inorganic filler with a resin or a film is suitably used. In addition, such an electronic component may be produced by laminating a plurality of members, and a high-dielectric material or a low-dielectric material may be suitably used according to the purpose of each layer, or a combination of a high-dielectric material and a low-dielectric material may be suitably used.

For example, JP2017-14406A discloses a resin composition containing an epoxy resin, a dielectric powder, a nonionic surfactant 70 that suppresses the generation of an aggregate of the dielectric powder, and a curing agent. In addition, JP2021-187969A discloses a high-dielectric resin composition containing an epoxy resin and an inorganic filler. Furthermore, WO2022/124396A discloses a high-dielectric resin composition containing a curable resin containing an epoxy resin, a curing agent containing an active ester compound, and an inorganic filler.

In recent years, the requirement level for the reliability of a signal has been increasing, and there is an increasing demand for reducing the dielectric loss tangent of a dielectric used in an electronic component to reduce the loss and improve the signal quality.

### SUMMARY OF THE INVENTION

The present inventors have found that a film exhibiting a desired relative permittivity and a dielectric loss tangent in a wider range can be produced by focusing on the alignment state of the filler. In particular, the present inventors have found that a film that achieves both a high permittivity or a low permittivity and a low dielectric loss tangent can be produced by focusing on the alignment state of the inorganic filler. In addition, the present inventors have found that the permittivity can be controlled even with a small amount of the inorganic filler by controlling the alignment state of the inorganic filler, and the mechanical properties of the film can be improved.

An object to be achieved by an embodiment of the present disclosure is to provide a film (preferably, a resin film) exhibiting a desired relative permittivity and a dielectric loss tangent in a wide range, a laminated film, a laminated plate, an electronic component such as a printed wiring board, an antenna substrate, and a high-frequency antenna module, a metamaterial that acts on a high-frequency signal, and an electromagnetic wave absorbing film. Specific methods for achieving the object are as follows.
<1> A film comprising:
   a filler; and a resin,
   in which the filler is at least one selected from the group consisting of an inorganic filler and an organic filler, and a ratio (Do/Di) of a number (Do) of particles of the filler per unit area in a thickness direction to a number (Di) of particles of the filler per unit area in an in-plane direction is 0.5 or more.
<2> The film according to <1>, in which the film contains the inorganic filler and the resin.
<3> The film according to <2>, in which a relative permittivity of the inorganic filler is 1 to 20,000.
<4> The film according to <2>, in which a relative permittivity of the inorganic filler is 6 to 20,000.
<5> The film according to any one of <2> to <4>, in which the inorganic filler includes at least one selected from the group consisting of barium titanate, strontium titanate, calcium titanate, magnesium titanate, bismuth titanate, zirconium titanate, zinc titanate, titanium dioxide, magnesium oxide, alumina, tantalum pentoxide, and niobium pentoxide.
<6> The film according to <1>, in which the film contains the organic filler and the resin.
<7> The film according to <1>, in which a relative permittivity of the filler is 1 to 6.
<8> The film according to any one of <1> to <7>, in which an average particle diameter of the filler is 0.01 μm to 10 μm.
<9> The film according to any one of <1> to <8>, in which a content of the filler is 1% by volume to 95% by volume with respect to a total amount of the film.
<10> The film according to any one of <1> to <9>, in which the resin includes at least one selected from the group consisting of a thermoplastic resin, a thermoplastic elastomer, a semi-cured product of a thermosetting resin, a semi-cured product of a photocurable resin, a cured product of the thermosetting resin, a cured product of a photocurable resin, a semi-cured product of a thermosetting elastomer, a semi-cured product of a photocurable elastomer, a cured product of the thermosetting elastomer, and a cured product of the photocurable elastomer.
<11> The film according to <10>, in which the thermosetting resin or the photocurable resin is an epoxy resin, and the film further comprises an active ester compound as a curing agent.
<12> The film according to any one of <1> to <11>,
in which the film includes a plurality of layers A containing 50% by volume or more of the filler, and a layer B containing the resin, and
the plurality of layers A and the layer B are disposed in the same plane, and the plurality of layers A are disposed so as not to be in contact with each other.
<13> The film according to <12>,
in which the film includes a resin layer C, and
the resin layer C is in contact with the layers A and the layer B.
<14> The film according to any one of <1> to <13>, having a surface roughness of 5 μm or less.
<15> A laminated film comprising a plurality of films according to any one of <1> to <14>stacked such that the films are in contact with each other.
<16> A laminated plate comprising:
   the film according to any one of <1> to <14>; and
   a metal layer or a metal pattern disposed on at least one surface of the film.
<17> A printed wiring board comprising the laminated plate according to <16>.
<18> An antenna substrate comprising the laminated plate according to <16>.
<19> An antenna module comprising the antenna substrate according to <18>, in which the antenna module is configured to perform at least one of transmission or reception of radio waves having a frequency of 6 to 24 GHz.
<20> An antenna module comprising the antenna substrate according to <18>, in which the antenna module is configured to perform at least one of transmission or reception of radio waves having a frequency of 0.5 to 5.9 GHZ.
<21> A metamaterial comprising a pattern provided on at least one surface of the film according to any one of <1> to <14>, in which the pattern is composed of at least one selected from the group consisting of a conductive material and a material that changes from an insulator to a conductor.
<22> An electromagnetic wave absorbing film comprising the metamaterial according to <21>.

According to one embodiment of the present disclosure, a film (preferably, a resin film) exhibiting a desired relative permittivity and a dielectric loss tangent in a wide range, a laminated film, and a laminated plate are provided. In addition, electronic components such as a printed wiring board, an antenna substrate, and a high-frequency antenna module using the resin film or the laminated plate, a metamaterial that acts on a high-frequency signal, and an electromagnetic wave absorbing film are provided.

### DESCRIPTION OF THE PREFERRED EMBODIMENTS

Hereinafter, the contents of the present disclosure will be described in detail. The description of configuration requirements below is made based on representative embodiments of the present disclosure in some cases, but the present disclosure is not limited to such embodiments.

In the present specification, a numerical range shown using “to” indicates a range including numerical values described before and after “to” as a lower limit value and an upper limit value.

In a numerical range described in a stepwise manner in the present disclosure, an upper limit value or a lower limit value described in one numerical range may be replaced with an upper limit or a lower limit in another numerical range described in a stepwise manner. In addition, in a numerical range described in the present disclosure, an upper limit value or a lower limit value described in the numerical range may be replaced with a value described in an example.

In addition, in a case where substitution or unsubstitution is not noted in regard to the notation of a “group” (atomic group) in the present specification, the “group” includes not only a group that does not have a substituent but also a group having a substituent. For example, the concept of an “alkyl group” includes not only an alkyl group that does not have a substituent (unsubstituted alkyl group) but also an alkyl group having a substituent (substituted alkyl group).

In the present specification, the concept of “(meth)acryl” includes both acryl and methacryl, and the concept of “(meth)acryloyl” includes both acryloyl and methacryloyl.

Further, the term “step” in the present specification indicates not only an independent step but also a step which cannot be clearly distinguished from other steps as long as the intended purpose of the step is achieved.

Furthermore, in the present disclosure, a combination of two or more preferred embodiments is a more preferred embodiment.

In addition, the weight-average molecular weight (Mw) and the number-average molecular weight (Mn) in the present disclosure are molecular weights converted using polystyrene as a standard substance by performing detection with a gel permeation chromatography (GPC) analysis apparatus using TSKgel SuperHM-H (trade name, manufactured by Tosoh Corporation) column, a solvent of pentafluorophenol (PFP) and chloroform at a mass ratio of 1:2, and a differential refractometer, unless otherwise specified.

An average particle diameter (for example, D50) of the inorganic filler in the present disclosure is measured using a laser diffraction/scattering-type particle size distribution analyzer. As a laser diffraction/scattering type particle diameter distribution analyzer, for example, LA-950V2 manufactured by Horiba, Ltd. is used.

A film of the present disclosure contains a filler, and a resin, the filler is at least one selected from the group consisting of an inorganic filler and an organic filler, and a ratio (Do/Di) of a number (Do) of particles of the filler per unit area in a thickness direction to a number (Di) of particles of the filler per unit area in an in-plane direction is 0.5 or more. In a case where a film is produced from a liquid resin composition, Do/Di can be increased by, for example, the following method, and in a film produced by a normal method, Do/Di is about 0.4.

Examples of a method of increasing Do/Di include a method of increasing a concentration of solid contents to 20% by mass or more; a method of increasing a viscosity of a liquid to 10 cP or more; a method of controlling a dispersion condition to control an aggregation state of the inorganic filler and control a buoyancy, and controlling a drying or curing condition with hot air to express a contraction force in the in-plane direction and promote the alignment of the inorganic filler in the thickness direction; and a method of using a shrinkable substrate, and causing the substrate to contract after the liquid resin composition is gelled or formed into a film to promote the alignment of the inorganic filler in the thickness direction.

According to the film of the present disclosure, a desired relative permittivity and a dielectric loss tangent are obtained in a wide range.

In particular, in a case where the filler is an inorganic filler, it is possible to achieve both a high permittivity or a low permittivity and a low dielectric loss tangent.

In the film in which Do/Di is 0.5 or more, since the inorganic filler is moderately aligned in the thickness direction, the amount of dielectric in the electric field direction increases, and the permittivity is efficiently increased. On the other hand, since the dielectric loss tangent changes depending on the amount of the inorganic filler added, the alignment of the inorganic filler in the thickness direction is promoted, so that the relative permittivity and the dielectric loss tangent are in a suitable range.

On the other hand, JP2017-14406A, JP2021-187969A, and WO2022/124396A do not have any description focusing on Do/Di.

Hereinafter, each component contained in the film according to the present disclosure will be described in detail.

The film of the present disclosure includes a filler.

The filler is at least one selected from the group consisting of an inorganic filler and an organic filler.

The filler may be an inorganic filler, may be an organic filler, or may be a mixture of an inorganic filler and an organic filler.

It is preferable that the filler has a relative permittivity of 1 to 20,000 at 25° C. and a measurement frequency of 10 GHz. In a high permittivity application, the relative permittivity of the filler is more preferably 6 to 20,000 and still more preferably 20 to 20,000. In a low permittivity application, the relative permittivity of the filler is more preferably 1 to 6 and still more preferably 1 to 4.

From the viewpoint of achieving both the alignment state of the filler and the dielectric characteristics, an average particle diameter of the filler is preferably 0.01 μm to 10 μm, more preferably 0.02 μm to 2 μm, and particularly preferably 0.03 μm to 5 μm. It is also possible to use a mixture of two or more types of fillers having different average particle diameters or to use a spherical filler, and in a case where such a filler is used, there is also a preferred effect that the mechanical properties of the film are improved.

From the viewpoint of achieving both the dielectric characteristics and the mechanical properties, a content of the filler is preferably 1% by volume to 95% by volume and more preferably 10% by volume to 60% by volume with respect to the total amount of the film. In a case where a mixture of two or more types of fillers having different average particle diameters is used, or in a case where a spherical filler is used, the content of the filler is preferably 10% by volume to 80% by volume.

### [Inorganic Filler]

It is preferable that the filler of the present disclosure contains an inorganic filler and a resin.

Examples of the inorganic filler used in the present disclosure include barium titanate, strontium titanate, calcium titanate, magnesium titanate, bismuth titanate, zirconium titanate, zinc titanate, titanium dioxide, magnesium oxide, alumina, tantalum pentoxide, and niobium pentoxide.

It is preferable that the inorganic filler includes at least one selected from the group consisting of barium titanate, strontium titanate, calcium titanate, magnesium titanate, bismuth titanate, zirconium titanate, zinc titanate, titanium dioxide, magnesium oxide, alumina, tantalum pentoxide, and niobium pentoxide. In addition, the inorganic filler may be obtained by performing calcination after adding a dopant compound containing other elements. In the inorganic filler calcined in this way, the permittivity may be increased.

Among these, from the viewpoint of high permittivity and low dielectric loss tangent, the inorganic filler is preferably barium titanate, titanium oxide, strontium titanate, calcium titanate, or zirconium titanate. Two or more types of inorganic fillers may be used in combination.

Commercially available products can be used as the inorganic filler.

It is preferable that the inorganic filler has a relative permittivity of 1 to 20,000 at 25° C. and a measurement frequency of 10 GHz. In a high permittivity application, the relative permittivity of the inorganic filler is more preferably 6 to 20,000 and still more preferably 20 to 20,000. In a low permittivity application, the relative permittivity of the inorganic filler is more preferably 1 to 6 and still more preferably 1 to 4.

In addition, from the viewpoint of achieving both the alignment state of the inorganic filler and the dielectric characteristics, an average particle diameter of the inorganic filler is preferably 0.01 μm to 50 μm, more preferably 0.05 μm to 30 μm, and particularly preferably 0.1 μm to 20 μm. The inorganic filler may be a mixture of two or more types of fillers having different average particle diameters.

A shape of the inorganic filler is not particularly limited, and the inorganic filler may be amorphous, spherical, or elliptical. Among these, the inorganic filler is preferably spherical. In a case of being spherical, the content in the resin composition can be increased, and the permittivity can be further increased.

One type or two or more types of the inorganic fillers can be used. From the viewpoint of achieving both the dielectric characteristics and the mechanical properties, a content of the inorganic filler is preferably 1% by volume to 95% by volume and more preferably 10% by volume to 60% by volume with respect to the total amount of the film. In a case where a mixture of two or more types of fillers having different average particle diameters is used, or in a case where a spherical filler is used, the content of the inorganic filler is preferably 10% by volume to 80% by volume.

In addition, the inorganic filler may be surface-treated with an inorganic substance or an organic substance. Examples of the method of the surface treatment include (1) modification by coating, (2) topochmical modification, (3) modification by a mechanochemical reaction, (4) modification by encapsulation, and (5) combination with radiation irradiation.

### [Organic Filler]

It is preferable that the filler of the present disclosure contains an organic filler and a resin.

As the organic filler, a known organic filler can be used.

Examples of a material of the organic filler include polyethylene, polystyrene, urea-formalin filler, polyester, cellulose, acrylic resin, fluororesin, cured epoxy resin, crosslinked benzoguanamine resin, crosslinked acrylic resin, a liquid crystal polymer (LCP), and a material containing two or more kinds of these.

Among these, from a viewpoint of reducing the dielectric loss tangent of the film, the organic filler preferably includes at least one selected from the group consisting of a liquid crystal polymer, fluororesin, an elastomer, and polyethylene; more preferably includes at least one kind selected from the group consisting of liquid crystal polyester, polytetrafluoroethylene, polystyrene-based elastomer, and polyethylene.

It is preferable that the organic filler has a relative permittivity of 1 to 6 and more preferably 1 to 4 at 25° C. and a measurement frequency of 10 GHz. In addition, from the viewpoint of achieving both the alignment state of the organic filler and the dielectric characteristics, an average particle diameter of the organic filler is preferably 0.01 μm to 10 μm, more preferably 0.02 μm to 2 μm, and particularly preferably 0.03 μm to 5 μm.

A shape of the organic filler is not particularly limited, and the inorganic filler may be amorphous, spherical, or elliptical. Among these, the organic filler is preferably spherical. In a case of being spherical, the content in the resin composition can be increased, and the permittivity can be further increased.

One type or two or more types of the organic fillers can be used. From the viewpoint of achieving both the dielectric characteristics and the mechanical properties, a content of the organic filler is preferably 1% by volume to 95% by volume and more preferably 10% by volume to 60% by volume with respect to the total amount of the film. In a case where a mixture of two or more types of fillers having different average particle diameters is used, or in a case where a spherical filler is used, the content of the organic filler is preferably 10% by volume to 80% by volume.

### [Resin]

Examples of the resin used in the present disclosure include a thermoplastic resin, a thermoplastic elastomer, a semi-cured product or a cured product of a thermosetting resin or a photocurable resin, and a semi-cured product or a cured product of a thermosetting elastomer or a photocurable elastomer. As necessary, a curing agent (initiator) or a curing accelerator can be added to these resins.

It is preferable that the resin includes at least one selected from the group consisting of a thermoplastic resin, a thermoplastic elastomer, a semi-cured product of a thermosetting resin, a cured product of a thermosetting resin, a semi-cured product of a thermosetting elastomer, and a cured product of a thermosetting elastomer.

Examples of the thermoplastic resin include a polyester resin (including a liquid crystal polymer), a cyanate resin, a coumarone resin, a polyurethane resin, a (meth)acrylic resin, a polystyrene resin, a fluororesin, a polyimide resin, a fluorinated polyimide resin, a polyamide resin, a polyamideimide resin, a polyether imide resin, a cellulose acylate resin, a polyurethane resin, a polyether ether ketone resin, a polycarbonate resin, a polyolefin resin (for example, a polyethylene resin, a polypropylene resin, a resin consisting of a cyclic olefin copolymer, and an alicyclic polyolefin resin), a polyarylate resin, a polyether sulfone resin, a polysulfone resin, a fluorene ring-modified polycarbonate resin, an alicyclic ring-modified polycarbonate resin, and a fluorene ring-modified polyester resin.

Examples of the thermoplastic elastomer include an elastomer (polystyrene-based elastomer) containing a constitutional unit derived from styrene, a polyester-based elastomer, a polyolefin-based elastomer, a polyurethane-based elastomer, a polyamide-based elastomer, a polyacryl-based elastomer, a silicone-based elastomer, a polyimide-based elastomer, and the like. The thermoplastic elastomer may be a hydride.

Examples of the polystyrene-based elastomer include a styrene-butadiene-styrene block copolymer (SBS), a styrene-isoprene-styrene block copolymer (SIS), a polystyrene-poly(ethylene-propylene) diblock copolymer (SEP), a polystyrene-poly(ethylene-propylene)-polystyrene triblock copolymer (SEPS), a styrene-ethylene-butylene-styrene block copolymer (SEBS), a polystyrene-poly(ethylene/ethylene-propylene)-polystyrene triblock copolymer (SEEPS), a styrene-isobutylene-styrene block copolymer (SIBS), and hydrides thereof.

Examples of the thermosetting resin include an epoxy resin which is a monomer, oligomer, or polymer having two or more epoxy groups in one molecule, a phenol resin, a melamine resin, a urea resin, an unsaturated polyester resin, an alkyd resin, a urethane resin, a polyimide resin such as a bismaleimide resin, a polyamide resin, a polyamideimide resin, a silicone resin, and an acrylic resin, and the molecular weight and molecular structure thereof are not particularly limited. From the viewpoint of formability and electrical characteristics, the thermosetting resin is preferably at least one selected from the group consisting of an epoxy resin and a polyimide resin, more preferably at least one selected from the group consisting of an epoxy resin and a bismaleimide resin, and still more preferably an epoxy resin.

Specific examples of the epoxy resin include a biphenyl-type epoxy resin; a bisphenol-type epoxy resin such as a bisphenol A-type epoxy resin, a bisphenol F-type epoxy resin, and a tetramethylbisphenol F-type epoxy resin; a stilbene-type epoxy resin; a novolac-type epoxy resin such as a phenol novolac-type epoxy resin and a cresol novolac-type epoxy resin; a polyfunctional epoxy resin such as a triphenylmethane-type epoxy resin and an alkyl-modified triphenylmethane-type epoxy resin; an aralkyl-type epoxy resin such as a phenol aralkyl-type epoxy resin having a phenylene skeleton and a phenol aralkyl-type epoxy resin having a phenylene skeleton; a naphthol-type epoxy resin such as a dihydroxynaphthalene-type epoxy resin and an epoxy resin obtained by glycidyl etherifying a dimer of dihydroxynaphthalene; a triazine nucleus-containing epoxy resin such as triglycidyl isocyanurate and monoallyl diglycidyl isocyanurate; and a bridged cyclic hydrocarbon compound-modified phenol-type epoxy resin such as a dicyclopentadiene-modified phenol-type epoxy resin. These may be used alone or in combination of two or more kinds thereof.

Among these, from the viewpoint of improving the balance between moisture resistance reliability and formability, the epoxy resin preferably includes one or two or more kinds selected from the group consisting of a bisphenol-type epoxy resin, a novolac-type epoxy resin, a biphenyl-type epoxy resin, a phenol aralkyl-type epoxy resin, and a triphenylmethane-type epoxy resin, and more preferably includes at least one selected from the group consisting of a biphenyl-type epoxy resin and a phenol aralkyl-type epoxy resin.

In addition, the composition can contain a curing agent that reacts with the epoxy resin to be cured, and examples thereof include amines such as linear aliphatic diamines having 2 to 20 carbon atoms, such as ethylenediamine, trimethylenediamine, tetramethylenediamine, and hexamethylenediamine, metaphenylenediamine, paraphenylenediamine, paraphenylene diamine, active ester compounds, 4,4′-diaminodiphenylmethane, 4,4′-diaminodiphenylpropane, 4,4′-diaminodiphenyl ether, 4,4′-diaminodiphenyl sulfone, 4,4′-diaminodicyclohexane, bis(4-aminophenyl)phenylmethane, 1,5-diaminonaphthalene, metaxylene diamine, paraxylenediamine, 1,1-bis(4-aminophenyl)cyclohexane, and dicyanodiamide; resol-type phenol resins such as aniline-modified resol resin and dimethyl ether resol resin; novolac-type phenol resins such as a phenol novolac resin, a cresol novolac resin, a tert-butylphenol novolac resin, and a nonylphenol novolac resin; polyfunctional phenol resins such as a triphenylmethane-type phenol resin; phenol aralkyl resins such as a phenol aralkyl resin containing a phenylene skeleton and a phenol aralkyl resin containing a biphenylene skeleton; phenol resins having a fused polycyclic structure such as a naphthalene skeleton or an anthracene skeleton; polyoxystyrene such as poly(paraoxystyrene); acid anhydrides such as alicyclic acid anhydrides such as hexahydrophthalic anhydride (HHPA) and methyltetrahydrophthalic anhydride (MTHPA), aromatic acid anhydrides such as trimellitic anhydride (TMA), pyromellitic anhydride (PMDA), and benzophenone tetracarboxylic anhydride (BTDA); polymeric mercaptan compounds such as polysulfide, thioester, and thioether; isocyanate compounds such as an isocyanate prepolymer and a blocked isocyanate; organic acids such as a carboxylic acid-containing polyester resin; and polyaminoamides. These may be used alone or in combination of two or more kinds thereof.

The curing agent is not particularly limited, but can be selected according to the type of the curable resin, desired characteristics of the resin composition for molding, and the like, as a compound that initiates a curing reaction. As the curing agent, a known thermal initiator or photoinitiator may be used alone or in combination of two or more kinds thereof. In addition, it is preferable that the curing agent contains at least one kind of active ester compound. Two or more kinds of active ester compounds may be used in combination. Here, the active ester compound refers to a compound having one or more ester groups in one molecule that reacts with an epoxy group and has a curing action on an epoxy resin. In a case where the curing agent contains an active ester compound, the curing agent may contain a curing agent other than the active ester compound or may not contain a curing agent other than the active ester compound.

In a case where an active ester compound is used as the curing agent, the dielectric loss tangent of the cured product can be reduced as compared with a case where another curing agent is used.

In a reaction between the epoxy resin and a phenol curing agent or an amine curing agent, a secondary hydroxyl group is generated. On the other hand, in a reaction between the epoxy resin and the active ester compound, an ester group is generated instead of the secondary hydroxyl group. Since the ester group has lower polarity than the secondary hydroxyl group, the resin composition for molding containing an active ester compound as a curing agent can suppress the dielectric loss tangent of the cured product to be lower than that of the resin composition for molding containing only a curing agent that generates a secondary hydroxyl group as a curing agent.

In addition, the polar group in the cured product increases the water absorbency of the cured product, but the concentration of the polar group in the cured product can be suppressed by using the active ester compound as the curing agent, and the water absorbency of the cured product can be suppressed. By suppressing the water absorbency of the cured product, that is, by suppressing the content of water molecules, which are polar molecules, the dielectric loss tangent of the cured product can be further suppressed.

The kind of the active ester compound is not particularly limited as long as it is a compound having one or more ester groups in a molecule that reacts with an epoxy group, and examples thereof include a phenol ester compound, a thiophenol ester compound, an N-hydroxyamine ester compound, and an esterified product of a heterocyclic hydroxy compound.

From the viewpoint of suppressing the dielectric loss tangent of the cured product, an equivalent ratio (ester group/epoxy group) of the epoxy resin to the active ester compound is preferably 0.9 or more, more preferably 0.95 or more, and still more preferably 0.97 or more.

From the viewpoint of suppressing the unreacted amount of the active ester compound, the equivalent ratio (ester group/epoxy group) of the epoxy resin to the active ester compound is preferably 1.1 or less, more preferably 1.05 or less, and still more preferably 1.03 or less.

An addition amount of the curing agent is not particularly limited, but for example, in a case where the entire resin composition is 100% by mass, the addition amount is preferably 0.1% by mass to 20% by mass, more preferably 0.5% by mass to 10% by mass or less, and still more preferably 1% by mass to 5% by mass.

It is preferable that the semi-cured product of the thermosetting resin and the cured product of the thermosetting resin are obtained by semi-curing and curing the above-described thermosetting resin, respectively.

Examples of the thermosetting elastomer include curable elastomers such as silicone rubber, fluororubber, and urethane rubber.

Examples of the silicone rubber include vinyl group-containing organopolysiloxane.

It is preferable that the semi-cured product of the thermosetting elastomer and the cured product of the thermosetting elastomer are obtained by semi-curing and curing the above-described thermosetting resin, respectively.

The curing accelerator is not particularly limited, but can be selected according to the type of the curable resin, desired characteristics of the resin composition for molding, and the like, as a compound that promotes a curing reaction. Two or more kinds of curing accelerators may be used in combination.

Among these, the resin preferably includes a liquid crystal polymer.

The type of the liquid crystal polymer is not particularly limited, and a known liquid crystal polymer can be used.

In addition, the liquid crystal polymer may be a thermotropic liquid crystal polymer which exhibits liquid crystallinity in a molten state, or may be a lyotropic liquid crystal polymer which exhibits liquid crystallinity in a solution state. In addition, in a case of the thermotropic liquid crystal, it is preferable that the liquid crystal is melted at a temperature of 450° C. or lower.

Examples of the liquid crystal polymer include a liquid crystal polyester, a liquid crystal polyester amide in which an amide bond is introduced into the liquid crystal polyester, a liquid crystal polyester ether in which an ether bond is introduced into the liquid crystal polyester, and a liquid crystal polyester carbonate in which a carbonate bond is introduced into the liquid crystal polyester.

In addition, as the liquid crystal polymer, from the viewpoint of liquid crystallinity, a polymer having an aromatic ring is preferable, and an aromatic polyester or an aromatic polyester amide is more preferable.

The liquid crystal polymer may be a polymer in which an imide bond, a carbodiimide bond, a bond derived from an isocyanate, such as an isocyanurate bond, or the like is further introduced into the aromatic polyester or the aromatic polyester amide.

In addition, it is preferable that the liquid crystal polymer is a fully aromatic liquid crystal polymer formed of only an aromatic compound as a raw material monomer.

Examples of the liquid crystal polymer include the following liquid crystal polymers.
1) A liquid crystal polymer obtained by polycondensing (i) an aromatic hydroxycarboxylic acid, (ii) an aromatic dicarboxylic acid, and (iii) at least one compound selected from the group consisting of an aromatic diol, an aromatic hydroxyamine, and an aromatic diamine.
2) A liquid crystal polymer obtained by polycondensing a plurality of types of aromatic hydroxycarboxylic acids.
3) A liquid crystal polymer obtained by polycondensing (i) an aromatic dicarboxylic acid and (ii) at least one compound selected from the group consisting of an aromatic diol, an aromatic hydroxyamine, and an aromatic diamine.
4) A liquid crystal polymer obtained by polycondensing (i) polyester such as polyethylene terephthalate and (ii) an aromatic hydroxycarboxylic acid.

Here, the aromatic hydroxycarboxylic acid, the aromatic dicarboxylic acid, the aromatic diol, the aromatic hydroxyamine, and the aromatic diamine may be each independently replaced with a polycondensable derivative.

The melting point of the liquid crystal polymer is preferably higher than 260° C., more preferably higher than 260° C. and 350° C. or lower, and still more preferably higher than 260° C. and 330° C. or lower.

In the present disclosure, the melting point is measured using a differential scanning calorimetry device. For example, the measurement is performed using product name “DSC-60A Plus” (manufactured by Shimadzu Corporation). A temperature increase rate in the measurement is set to 10° C./minute.

The weight-average molecular weight of the liquid crystal polymer is preferably 1,000,000 or less, more preferably 3,000 to 300,000, still more preferably 5,000 to 100,000, and particularly preferably 5,000 to 30,000.

The liquid crystal polymer preferably includes aromatic polyester amide from a viewpoint of further decreasing the dielectric loss tangent. Aromatic polyester amide is resin having at least one aromatic ring and having an ester bond and an amide bond. Among these, from the viewpoint of heat resistance, the aromatic polyester amide is preferably a fully aromatic polyester amide.

Aromatic polyester amide is preferably a crystalline polymer. The first phase preferably contains a crystalline aromatic polyester amide. In a case where the aromatic polyester amide is crystalline, the dielectric loss tangent is further reduced.

The crystalline polymer refers to a polymer having a clear endothermic peak, not a stepwise endothermic amount changed, in differential scanning calorimetry (DSC). Specifically, for example, this means that a half-width of an endothermic peak in measuring at a temperature increase rate 10° C./minute is within 10° C. A polymer in which a half-width exceeds 10° C. and a polymer in which a clear endothermic peak is not recognized are distinguished as an amorphous polymer from a crystalline polymer.

Aromatic polyester amide preferably contains a constitutional unit represented by Formula 1, a constitutional unit represented by Formula 2, and a constitutional unit represented by Formula 3.

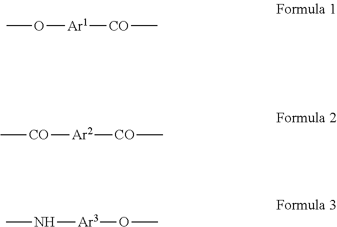

In Formula 1 to Formula 3, Ar¹, Ar², and Ar³ each independently represent a phenylene group, a naphthylene group, or a biphenylylene group.

Hereinafter, the constitutional unit represented by Formula 1 and the like are also referred to as “unit 1” and the like.

The unit 1 can be introduced, for example, using aromatic hydroxycarboxylic acid as a raw material.

The unit 2 can be introduced, for example, using aromatic dicarboxylic acid as a raw material.

The unit 3 can be introduced, for example, using aromatic hydroxylamine as a raw material.

Here, the aromatic hydroxycarboxylic acid, the aromatic dicarboxylic acid, the aromatic diol, and the aromatic hydroxylamine may be each independently replaced with a polycondensable derivative.

For example, the aromatic hydroxycarboxylic acid and the aromatic dicarboxylic acid can be replaced with aromatic hydroxycarboxylic acid ester and aromatic dicarboxylic acid ester, by converting a carboxy group into an alkoxycarbonyl group or an aryloxycarbonyl group.

The aromatic hydroxycarboxylic acid and the aromatic dicarboxylic acid can be replaced with aromatic hydroxycarboxylic acid halide and aromatic dicarboxylic acid halide, by converting a carboxy group into a haloformyl group.

The aromatic hydroxycarboxylic acid and the aromatic dicarboxylic acid can be replaced with aromatic hydroxycarboxylic acid anhydride and aromatic dicarboxylic acid anhydride, by converting a carboxy group into an acyloxycarbonyl group.

Examples of a polycondensable derivative of a compound having a hydroxy group, such as aromatic hydroxycarboxylic acid or aromatic hydroxyamine, include a derivative (acylated product) obtained by acylating the hydroxy group to convert the acylated group into an acyloxy group.

For example, the aromatic hydroxycarboxylic acid and the aromatic hydroxylamine can be each replaced with an acylated product by acylating a hydroxy group and converting the acylated group into an acyloxy group.

Examples of a polycondensable derivative of the aromatic hydroxylamine include a derivative (acylated product) obtained by acylating an amino group to convert the acylated group into an acylamino group.

For example, the aromatic hydroxyamine can be replaced with an acylated product by acylating an amino group to convert the acylated group into an acylamino group.

In Formula 1, Ar¹ is preferably a p-phenylene group, a 2,6-naphthylene group, or a 4,4′-biphenylylene group, and more preferably a 2,6-naphthylene group.

In a case where Ar¹ is a p-phenylene group, the unit 1 is, for example, a constitutional unit derived from p-hydroxybenzoic acid.

In a case where Ar¹ is a 2,6-naphthylene group, the unit 1 is, for example, a constitutional unit derived from 6-hydroxy-2-naphthoic acid.

In a case where Ar¹ is a 4,4′-biphenylylene group, the unit 1 is, for example, a constitutional unit derived from 4′-hydroxy-4-biphenylcarboxylic acid.

In Formula 2, Ar² is preferably a p-phenylene group, an m-phenylene group, or a 2,6-naphthylene group, and more preferably an m-phenylene group.

In a case where Ar² is a p-phenylene group, the unit 2 is, for example, a constitutional unit derived from terephthalic acid.

In a case where Ar² is an m-phenylene group, the unit 2 is, for example, a constitutional unit derived from isophthalic acid.

In a case where Ar² is a 2,6-naphthylene group, the unit 2 is, for example, a constitutional unit derived from 2,6-naphthalenedicarboxylic acid.

In Formula 3, Ar³ is preferably a p-phenylene group or a 4,4′-biphenylylene group, and more preferably a p-phenylene group.

In a case where Ar³ is a p-phenylene group, the unit 3 is, for example, a constitutional unit derived from p-aminophenol.

In a case where Ar³ is a 4,4′-biphenylylene group, the unit 3 is, for example, a constitutional unit derived from 4-amino-4′-hydroxybiphenyl.

With respect to the total content of the unit 1, the unit 2, and the unit 3, a content of the unit 1 is preferably 30 mol % or more, a content of the unit 2 is preferably 35% or less, and a content of the unit 3 is preferably 35 mol % or less.

The content of the unit 1 is preferably 30 mol % to 80 mol %, more preferably 30 mol % to 60 mol %, and particularly preferably 30 mol % to 40 mol % with respect to the total content of the unit 1, the unit 2, and the unit 3.

The content of the unit 2 is preferably 10 mol % to 35 mol %, more preferably 20 mol % to 35 mol %, and particularly preferably 30 mol % to 35 mol % with respect to the total content of the unit 1, the unit 2, and the unit 3.

The content of the unit 3 is preferably 10 mol % to 35 mol %, more preferably 20 mol % to 35 mol %, and particularly preferably 30 mol % to 35 mol % with respect to the total content of the unit 1, the unit 2, and the unit 3.

The total content of the constitutional units is a value obtained by totaling a substance amount (mol) of each constitutional unit. The substance amount of each constitutional unit is calculated by dividing a mass of each constitutional unit constituting aromatic polyester amide by a formula weight of each constitutional unit.

In a case where a ratio of the content of the unit 2 to the content of the unit 3 is expressed as [Content of unit 2]/[Content of unit 3] (mol/mol), the ratio is preferably 0.9/1 to 1/0.9, more preferably 0.95/1 to 1/0.95, and still more preferably 0.98/1 to 1/0.98.

Aromatic polyester amide may have two kinds or more of the unit 1 to the unit 3 each independently. Alternatively, aromatic polyester amide may have other constitutional units other than the unit 1 to the unit 3. A content of other constitutional units is preferably 10% by mole or less and more preferably 5% by mole or less with respect to the total content of all constitutional units.

Aromatic polyester amide is preferably produced by subjecting a source monomer corresponding to the constitutional unit constituting the aromatic polyester amide to melt polymerization.

The weight-average molecular weight of aromatic polyester amide is preferably 1,000,000 or less, more preferably 3,000 to 300,000, still more preferably 5,000 to 100,000, and particularly preferably 5,000 to 30,000.

The film may contain only one kind of resin or two or more kinds of resins.

From the viewpoint of achieving both the dielectric characteristics and the mechanical properties, a content of the resin is preferably 10% by volume to 90% by volume, more preferably 20% by volume to 70% by volume, and still more preferably 30% by volume to 60% by volume.

The film may contain an additive in addition to the inorganic filler and the resin. Examples of the additive include a polymerization initiator, a dispersant, a surfactant, a crosslinking agent, an antioxidant, a flame retardant, a dielectric loss tangent reducer, a colorant, and a stress relaxer. Two or more kinds of additives may be used in combination.

### <Film Configuration>

It is preferable that the film of the present disclosure includes a plurality of layers A containing 50% by volume or more of the filler and a layer B containing the resin, the plurality of layers A and the layer B are disposed in the same plane, and the plurality of layers A are disposed not to be in contact with each other.

The filler is at least one selected from the group consisting of an inorganic filler and an organic filler.

In a case where the filler is an inorganic filler, it is preferable that the film of the present disclosure includes a plurality of layers A containing 50% by volume or more of the inorganic filler and a layer B containing the resin, the plurality of layers A and the layer B are disposed in the same plane, and the plurality of layers A are disposed not to be in contact with each other.

In the layer A, the content of the filler is preferably 50% by volume or more, more preferably 70% by volume or more, and still more preferably 80% by volume or more with respect to the total amount of the layer A. The upper limit value of the content of the filler is not particularly limited, and may be, for example, 100% by volume.

In a case where the filler is an inorganic filler, in the layer A, the content of the inorganic filler is preferably 50% by volume or more, more preferably 70% by volume or more, and still more preferably 80% by volume or more with respect to the total amount of the layer A. The upper limit value of the content of the inorganic filler is not particularly limited, and may be, for example, 100% by volume.

It is preferable that the layer A contains the resin in addition to the filler.

In the layer B, the content of the resin is preferably 60% by volume or more, more preferably 80% by volume or more, and still more preferably 90% by volume or more with respect to the total amount of the layer B. The content of the resin may be 100% by volume.

A shape of the layer A is not particularly limited, and in a plan view of the film, the layer A may be a square, a rectangle, a polygon, or an irregular shape.

In addition, in a cross-sectional view of the film cut along the thickness direction, the shape of the layer A may be a square, a rectangle, or a trapezoid.

A disposition form of the plurality of layers A is not particularly limited, and the adjacent layers A may be aligned at a constant distance or may be in a mosaic shape or a honeycomb shape.

A width of the layer A is not particularly limited, but is preferably 100 μm to 400 μm and more preferably 200 μm to 300 μm.

The width of the layer A is measured by the following method.

The film is cut using a microtome in the thickness direction of the film. The cut surface is observed with an optical microscope or a scanning electron microscope, and the width of the layer A is measured. In a case where the layer A has an irregular shape, the width represents a length of a portion that is longest in the layer A and parallel to the film plane. In addition, an average value of values measured at any 10 points is used as the width of the layer A.

A distance between the adjacent layers A (hereinafter, also referred to as “distance between layers A”) is not particularly limited, but is preferably 5 μm to 100 μm and more preferably 30 μm to 70 μm.

The distance between layers A is measured by the following method.

The film is cut using a microtome in the thickness direction of the film. The cut surface is observed with an optical microscope or a scanning electron microscope. A distance between two adjacent layers A is measured. An average value of values measured at any 10 points is used as the distance between layers A.

An average thickness of the layer A and the layer B is not particularly limited, but is preferably 5 μm to 80 μm, more preferably 10 μm to 50 μm, and particularly preferably 20 μm to 40 μm.

It is preferable that the film of the present disclosure further includes a resin layer C, and the resin layer C is in contact with the layers A and the layer B. That is, it is preferable that no other layer is interposed between the layer A and the layer B and the resin layer C.

The resin layer C may be disposed on one surface of the layer A and the layer B, or may be disposed on both surfaces of the layer A and the layer B.

The resin layer C contains a resin. The resin contained in the resin layer C is not particularly limited, and may be the same as or different from the resin contained in the layer B.

An average thickness of the resin layer C is not particularly limited, but is preferably 0.3 μm to 10 μm, more preferably 0.5 μm to 5 μm, and still more preferably 0.5 μm to 2 μm.

In a case where the resin layer C is disposed on both surfaces of the layer A and the layer B, the average thickness of the resin layer C means an average value of the total thickness of the two resin layers C.

### <Physical Properties of Film>

### (Number of Fillers per Unit Area)

The number of fillers per unit area in the in-plane direction (Di) and the number of fillers per unit area in the thickness direction (Do) of the film of the present disclosure can be determined by evaluating the number of fillers per unit area by a form observation using a scanning electron microscope, as necessary, by creating a cut surface using a microtome. A ratio (Do/Di) is calculated from the obtained Di and Do.

In a case where the filler is an inorganic filler, the number of inorganic fillers per unit area in the in-plane direction (Di) and the number of inorganic fillers per unit area in the thickness direction (Do) of the film of the present disclosure can be determined by evaluating the number of inorganic fillers per unit area by a form observation using a scanning electron microscope, as necessary, by creating a cut surface using a microtome. A ratio (Do/Di) is calculated from the obtained Di and Do.

For example, in a case where the filler (for example, the inorganic filler) is aligned in the in-plane direction, Di increases, Do decreases, and Do/Di decreases. In a case where the filler (for example, the inorganic filler) is aligned in the film thickness direction, Di decreases, Do increases, and Do/Di increases.

In the present disclosure, in a liquid preparation step or a film formation step described later, the alignment state of the filler (for example, the inorganic filler) is controlled such that Do/Di is 0.5 or more, whereby the relative permittivity and the dielectric loss tangent can be set to suitable ranges. Do/Di is preferably 0.7 to 1,000, more preferably 0.85 to 100, and still more preferably 0.9 to 10.

In a case where Do/Di is 0.5 or more, the filler (for example, the inorganic filler) is moderately aligned in the thickness direction. As a result, the amount of dielectric in the electric field direction increases, and the relative permittivity in the electric field direction is efficiently increased, and at the same time, the amount of dielectric in the direction orthogonal to the electric field decreases, and the permittivity in the direction orthogonal to the electric field is efficiently decreased. On the other hand, since the dielectric loss tangent changes depending on the amount of the filler (for example, the inorganic filler) added, the alignment of the filler (for example, the inorganic filler) in the thickness direction is promoted, so that the relative permittivity and the dielectric loss tangent are in a suitable range.

### (Dielectric Characteristics)

In the film of the present disclosure, the relative permittivity is preferably 5 to 1,000 or 1 to 5, and more preferably 10 to 100 or 1 to 3.

In the present disclosure, the relative permittivity and the dielectric loss tangent are measured by the following method.

The dielectric loss tangent is measured by a resonance perturbation method at a frequency of 10 GHz. A 10 GHz cavity resonator (“CP531” manufactured by Kanto Electronic Application & Development Inc.) is connected to a network analyzer (“E8363B” manufactured by Agilent Technology Company), a film is inserted into the cavity resonator, and the measurement is performed from the change in resonance frequency before and after the insertion for 96 hours in an environment of a temperature of 25° C. and a humidity of 60% RH.

### (Thickness)

An average thickness of the film is not particularly limited, but is preferably 5 μm to 500 μm, more preferably 10 μm to 300 μm, and particularly preferably 15 μm to 100 μm.

The average thickness of the film is measured at optional five sites using an adhesive film thickness meter, for example, an electronic micrometer (product name, “KG3001A”, manufactured by Anritsu Corporation), and the average value of the measured values is defined as the average thickness of the film.

### (Surface Roughness)

The surface roughness of the film is preferably 5 μm or less and more preferably 3 μm or less. The lower limit value of the surface roughness of the film is not particularly limited, and is, for example, 0.0001 μm.

In a case where the surface roughness of the film is 5 μm or less, the transmission loss of the high-frequency signal can be further reduced.

The surface roughness of the film can be determined by evaluating a root mean square in a reference length by a surface observation using a laser microscope.

### <Film Manufacturing Step>

### (Film Formation)

A manufacturing method of the film is not particularly limited, and a known method can be referred to.

Suitable examples of the film forming method include a co-casting method, a multi-layer coating method, and a co-extrusion method, and the film can also be produced using a dispenser or the like.

In a case where the multi-layer structure is produced by a co-casting method or a multi-layer coating method, it is preferable to perform the co-casting method or the multi-layer coating method using a solution or the like obtained by dissolving or dispersing each component of each layer in a solvent.

It is preferable that the film manufacturing step includes a step of performing dispersion treatment with a beads mill to prepare a solution, and a step of forming a film using the solution.

By performing the dispersion treatment with the beads mill, an effect of reducing and homogenizing the aggregates of particles can be obtained.

A bead diameter used in the beads mill is preferably larger than an average particle diameter of particles used for preparing the solution. The bead diameter is, for example, 0.1 mm to 5 mm.

Examples of the solvent include halogenated hydrocarbons such as dichloromethane, chloroform, 1,1-dichloroethane, 1,2-dichloroethane, 1,1,2,2-tetrachloroethane, 1-chlorobutane, chlorobenzene, and o-dichlorobenzene; halogenated phenols such as p-chlorophenol, pentachlorophenol, and pentafluorophenol; ethers such as diethyl ether, tetrahydrofuran, and 1,4-dioxane; ketones such as acetone and cyclohexanone; esters such as ethyl acetate and γ-butyrolactone; carbonates such as ethylene carbonate and propylene carbonate; amines such as triethylamine; nitrogen-containing heterocyclic aromatic compounds such as pyridine; nitriles such as acetonitrile and succinonitrile; amides such as N,N-dimethylformamide, N,N-dimethylacetamide, and N-methylpyrrolidone; urea compounds such as tetramethylurea; nitro compounds such as nitromethane and nitrobenzene; sulfur compounds such as dimethyl sulfoxide and sulfolane; and phosphorus compounds such as hexamethylphosphoramide and tri-n-butyl phosphate. Among these, two or more kinds thereof may be used in combination.

From the viewpoint of low corrosiveness and satisfactory handleability, a solvent containing, as a main component, an aprotic compound, particularly an aprotic compound having no halogen atom is preferable as the solvent, and the proportion of the aprotic compound in the entire solvent is preferably 50% by mass to 100% by mass, more preferably 70% by mass to 100% by mass, and particularly preferably 90% by mass to 100% by mass. In addition, from the viewpoint of easily dissolving the liquid crystal polymer, as the above-described aprotic compound, it is preferable to use an amide such as N,N-dimethylformamide, N,N-dimethylacetamide, tetramethylurea, and N-methylpyrrolidone, or an ester such as γ-butyrolactone; and it is more preferable to use N,N-dimethylformamide, N,N-dimethylacetamide, or N-methylpyrrolidone.

In addition, as the solvent, from the viewpoint of easily dissolving the liquid crystal polymer, a solvent containing a compound having a dipole moment of 3 to 5 as a main component is preferable, and a proportion of the compound having a dipole moment of 3 to 5 in the entire solvent is preferably 50% by mass to 100% by mass, more preferably 70% by mass to 100% by mass, and particularly preferably 90% by mass to 100% by mass.

It is preferable to use the compound having a dipole moment of 3 to 5 as the above-described aprotic compound.

In addition, as the solvent, from the viewpoint of ease of removal, a solvent containing, as a main component, a compound having a boiling point of 220° C. or lower at 1 atm is preferable, and a proportion of the compound having a boiling point of 220° C. or lower at 1 atm in the entire solvent is preferably 50% by mass to 100% by mass, more preferably 70% by mass to 100% by mass, and particularly preferably 90% by mass to 100% by mass.

It is preferable to use the compound having a boiling point of 220° C. or lower at 1 atm as the above-described aprotic compound.

In addition, in a case where the manufacturing step of the film is the co-casting method, the multilayer coating method, the co-extrusion method, or the like described above, a support may be used.

Examples of the support include a metal drum, a metal band, a glass plate, a resin film, and a metal foil. Among these, the support is preferably a metal drum, a metal band, or a resin film.

In addition, the support may have a surface treatment layer formed on the surface so that the support can be easily peeled off. Hard chrome plating, a fluororesin, or the like can be used as the surface treatment layer.

The average thickness of the support is not particularly limited, but is preferably 25 μm to 75 μm and more preferably 50 μm to 75 μm.

In addition, a method for removing at least a part of the solvent from a cast or applied film-like composition (a coating film) is not particularly limited, and a known drying method can be used.

### (Stretching)

In the above-described manufacturing step of the film, stretching can be combined as appropriate from the viewpoint of controlling molecular alignment and adjusting thermal expansion coefficient and mechanical properties. The stretching method is not particularly limited, and a known method can be referred to, and the stretching method may be carried out in a solvent-containing state or in a dry film state. The stretching in the solvent-containing state may be carried out by gripping and stretching the laminate, or may be carried out by utilizing self-contraction due to drying without stretching. The stretching is particularly effective for the purpose of improving the breaking elongation and the breaking strength, in a case where the mechanical properties of the film are reduced by addition of an inorganic filler or the like.

### <Semi-Cured Product>

In the present disclosure, in a case where a curable resin is used, the resin can also be used as a sheet (prepreg) in a semi-cured state after being impregnated into a fibrous base material. Such a sheet has various excellent characteristics such as dielectric characteristics and mechanical and electrical connection reliability under high temperature and high humidity, and is suitable for manufacturing an insulating layer of a printed wiring board.

A method of impregnating the resin composition into the fibrous base material is not particularly limited, and examples thereof include a method of preparing a resin varnish by dissolving the resin composition in a solvent and immersing the fibrous base material in the resin varnish, a method of applying the resin varnish to the fibrous base material using various coaters, a method of spraying the resin varnish onto the fibrous base material, and a method of laminating both surfaces of the fibrous base material with the resin film consisting of the resin composition.

Examples of the above-described fibrous base material include a glass fiber base material such as glass cloth and glass nonwoven fabric, an inorganic fiber base material such as a cloth or a nonwoven fabric containing an inorganic compound other than glass as a component, and an organic fiber base material formed of organic fibers such as an aromatic polyamideimide resin, a polyamide resin, an aromatic polyester resin, a polyester resin, a polyimide resin, and a fluororesin. Among these base materials, in a case where a glass fiber base material represented by glass cloth is used from the viewpoint of strength, the mechanical strength and the heat resistance of the printed wiring board can be made to be favorable.

A thickness of the fibrous base material is not particularly limited, but is preferably 5 μm to 150 μm, more preferably 10 μm to 100 μm, and still more preferably 12 μm to 90 μm.

In a case where the thickness of the fibrous base material is equal to or less than the upper limit value, the impregnation property of the resin composition in the fibrous base material is improved, and the occurrence of strand voids and a decrease in insulation reliability can be suppressed, and it is also possible to easily form a through-hole with a laser. In addition, in a case where the thickness of the fibrous base material is equal to or more than the lower limit value, the strength of the fibrous base material or the prepreg can be improved, and it is effective from the viewpoint of handling properties, ease of producing the prepreg, and suppressing warpage of the resin substrate.

As the above-described glass fiber base material, for example, a glass fiber base material formed of one or two or more kinds of glasses selected from E glass, S glass, D glass, T glass, NE glass, UT glass, L glass, HP glass, and quartz glass is suitably used.

The prepreg can be used, for example, to form an insulating layer in a buildup layer or an insulating layer in a core layer in a printed wiring board. In a case where the prepreg is used to form an insulating layer in a core layer in a printed wiring board, for example, two or more pieces of the prepreg can be laminated, and the obtained laminate can be heated and cured to form an insulating layer for a core layer.

### <Metal Layer>

As the metal layer, for example, a rolled metal foil formed by a rolling method, an electrolytic metal foil formed by an electrolytic method, plating, sputtering, or the like can be selected.

The metal layer may be made of a material known in the related art, and is preferably made of silver or copper and more preferably made of copper.

The metal layer may be disposed on both surfaces of the film (including the prepreg). In this case, the two metal layers may be metal layers having the same material, thickness, and shape, or may be metal layers having different materials, thicknesses, and shapes. From the viewpoint of adjusting the characteristic impedance, the two metal layers may be metal base materials having different materials and thicknesses. As a result, a metal-clad laminated plate can be produced.

The average thickness of the metal layer is not particularly limited, but is preferably 0.01 μm to 20 μm, more preferably 0.1 μm to 18 μm, and still more preferably 1 μm to 12 μm.

### <Printed Wiring Board>

A printed wiring board can be produced from the above-described metal-clad laminated plate by a known method. In addition, the printed wiring board can also be applied to a semiconductor package as appropriate.

### <Antenna Substrate>

A pattern antenna can be produced from the above-described metal-clad laminated plate or printed wiring board by a known method such as photofabrication. The frequency of the antenna can be appropriately adjusted by designing the size of the pattern or the patch.

### <Antenna Module>

The antenna module including the above-described antenna substrate may be an antenna module that performs at least one of transmission or reception of radio waves having a frequency of 6 to 24 GHZ, or may be an antenna module that performs at least one of transmission or reception of radio waves having a frequency of 0.5 to 5.9 GHZ. The antenna module including the above-described antenna substrate is preferably an antenna module that performs transmission and reception of radio waves having a frequency of 6 to 24 GHz, and preferably an antenna module that performs transmission and reception of radio waves having a frequency of 0.5 to 5.9 GHZ.

### <Metamaterial>

A metamaterial can be produced by using the above-described film or metal-clad laminated plate, and forming a pattern composed of at least one of a conductive material or a material that changes from an insulator to a conductor on at least one surface of the film. It is preferable that the above-described pattern serves as a resonator with respect to electromagnetic waves having a frequency of 6 to 24 GHz.

The conductive material preferably contains a metal, and more preferably is one or more selected from the group consisting of gold, silver, platinum, copper, and aluminum.

A content of the metal with respect to the total mass of the conductive material is not particularly limited, and may be 80% by mass or more, 90% by mass or more, or 100% by mass.

As the material that changes from an insulator to a conductor, a material that is changed from an insulator to a conductor by heating, light irradiation, or application of a voltage can be used, and it is preferably one or more selected from the group consisting of a phase change material, a semiconductor, a conductive oxide, and a carbon material.

In the present disclosure, the phase change material means a material which causes a phase change between an amorphous phase and a crystal phase by Joule heat due to an electric pulse.

Examples of the phase change material include vanadium oxide, an antimony tellurium (SbTe) alloy, a germanium tellurium (GeTe) alloy, a germanium antimony tellurium (GeSbTe) alloy, an indium antimony tellurium (InSbTe) alloy, and a silver indium antimony tellurium (AgInSbTe) alloy. Among these, from the viewpoint of easily controlling a temperature and a voltage at which the insulator is transited to the conductor and the viewpoint of crack suppressibility, vanadium oxide or a GeSbTe alloy is preferable.

Examples of the semiconductor include a p-type π-conjugated polymer, a condensed polycyclic compound, a triarylamine compound, a hetero 5-membered ring compound, a phthalocyanine compound, and a porphyrin compound.

Examples of the conductive oxide include indium tin oxide (ITO), indium zinc oxide (IZO), zinc oxide (ZnO), and indium gallium zinc oxide (IGZO).

Examples of the carbon material include carbon nanotube and graphene.

The pattern may include a plurality of structural bodies. The pattern may include two or more structural bodies having different shapes, sizes, and the like.

### <Electromagnetic Wave Absorbing Film>

In addition, in a metamaterial using a high dielectric constant film according to the present disclosure, a reflective layer can be formed on the surface opposite to the surface on which the pattern is formed, and the thickness of the film (unit: μm) can be set to a value obtained by multiplying the wavelength of an electromagnetic wave having a frequency of 6 to 24 GHz by 0.25 and dividing the result by the square root of the relative dielectric constant of the film, thereby making it possible to produce an electromagnetic wave-absorbing film that is relatively thin and has low brittleness and followability.

### <Laminated Film>

The above-described films can be laminated such that the films are in contact with each other to produce a laminated film. A method of bonding the films to each other is not particularly limited, and examples thereof include a laminating method.

### EXAMPLES

Hereinafter, the present disclosure will be described in more detail with reference to Examples. The materials, the used amounts, the proportions, the treatment contents, the treatment procedures, and the like described in the following examples can be appropriately changed without departing from the gist of the present disclosure. Therefore, the scope of the present disclosure is not limited to the following specific examples.

### <<Examples 1A to 8A and Comparative Example 1>>

Details of each material used for preparing the film and the laminate are as follows.

### <Inorganic Filler>

F1: Pulverized product of barium titanate (average particle diameter: 0.18 μm, relative permittivity: 200, dielectric loss tangent: 0.015)
F2: Pulverized product of strontium titanate (average particle diameter: 1 μm, relative permittivity: 300, dielectric loss tangent: 0.0005)
F3: Pulverized product of titanium oxide (average particle diameter: 5 μm, relative permittivity: 90, dielectric loss tangent: 0.001)
F4: Pulverized product of calcium titanate (average particle diameter: 5 μm, relative permittivity: 200, dielectric loss tangent: 0.001)
F5: Hollow silica particles (product name “GLASS BUBBLES iM16K”, manufactured by 3M Company, average particle diameter: 20 μm, relative permittivity: 1.5, dielectric loss tangent: 0.005)

### <Organic Filler>

F6: Particles of polytetrafluoroethylene produced according to the following manufacturing method (average particle diameter: 10 μm, relative permittivity: 1.9, dielectric loss tangent: 0.0001)
70 L of deionized water was added to a polymerization tank made of stainless steel, which was equipped with a stirring blade, and air in the tank was removed, and then 100 g of ethane and tetrafluoroethylene (TFE) were added thereto to raise the temperature to 85° C. Thereafter, TFE was added again, and the pressure in the tank was adjusted to 0.8 MPa. 250 ppm/H₂O of ammonium persulfate and 250 ppm/H₂O of disuccinic peroxide were added in a state of an aqueous solution. The polymerization was carried out while maintaining the tank pressure and the temperature at 0.85 MPa and 85° C., respectively, and the polymerization reaction was terminated at a point in time when the TFE supply amount reached 12 kg, and the tank pressure was released to normal pressure. The inside of the tank was cooled to room temperature (25° C.), and then the obtained particles were washed with deionized water. The particles were filtered and dried in a hot air circulation type dryer at 170° C. for 12 hours to obtain polytetrafluoroethylene (PTFE) particles F6. A weight-average molecular weight of the obtained PTFE particles was 5,000, and an average particle diameter thereof was 10 μm.
F7: Particles of hydrogenated styrene-isobutylene-styrene block copolymer produced according to the following manufacturing method (average particle diameter: 10 μm, relative permittivity: 2.3, dielectric loss tangent: 0.0001) 452 mL of 1-chlorobutane, 319 mL of hexane, and 0.55 g of 1,4-bis(1-chloro-1-methylethyl)benzene were placed in a reaction container, cooled to −75° C., and then 5 mg of dimethylacetamide, 2.3 mL of isobutylene, and 0.08 mL of titanium tetrachloride were added thereto and stirred for 1.5 hours.

Next, 0.6 g of styrene was added to the reaction solution, and stirring was continued for 60 minutes, and then the contents of the reactor were put into water, and the organic layer and the aqueous layer were separated from each other. After the washing, the organic layer was poured into a large amount of methanol to precipitate the polymer, and the obtained polymer was vacuum-dried at 60° C. for 24 hours. The precipitate was pulverized with a pulverizer to obtain a powdery hydrogenated styrene-isobutylene-styrene block copolymer F7. A weight-average molecular weight of the hydrogenated styrene-isobutylene-styrene block copolymer F7 was 900, and an average particle diameter thereof was 10 μm.

### <Resin>

P1: Aromatic polyester amide prepared by the following preparation method

### -Synthesis of Aromatic Polyester Amide P1-

940.9 g (5.0 mol) of 6-hydroxy-2-naphthoic acid, 415.3 g (2.5 mol) of isophthalic acid, 377.9 g (2.5 mol) of acetaminophen, 867.8 g (8.4 mol) of acetic anhydride are put in a reactor comprising a stirring device, a torque meter, a nitrogen gas introduction pipe, a thermometer, and a reflux condenser, gas in the reactor is substituted with nitrogen gas, a temperature is raised from a room temperature (23° C., the same applies hereinafter) to 140° C. over 60 minutes while stirring under a nitrogen gas flow, and refluxing is performed at 140° C. for three hours.

Next, the temperature was raised from 150° C. to 300° C. over 5 hours while distilling off by-produced acetic acid and unreacted acetic anhydride, and maintained at 300° C. for 30 minutes. Thereafter, a content is taken out from the reactor and cooled to the room temperature. The obtained solid was pulverized by a pulverizer to obtain a powdered aromatic polyester amide Pla. A flow start temperature of the aromatic polyester amide Pla was 193° C. In addition, the aromatic polyester amide Pla was a fully aromatic polyester amide.

The aromatic polyester amide Pla was subjected to solid phase polymerization by increasing the temperature from room temperature to 160° C. over 2 hours and 20 minutes in a nitrogen atmosphere, increasing the temperature from 160° C. to 180° C. over 3 hours and 20 minutes, and maintaining the temperature at 180° C. for 5 hours, and then the resultant was cooled. Next, the resultant was pulverized by a pulverizer to obtain a powdered aromatic polyester amide P1b. A flow start temperature of the aromatic polyester amide P1b was 220° C.

Aromatic polyester amide P1b is subjected to solid phase polymerization by raising the temperature from the room temperature to 180° C. for one hour and 25 minutes, next increasing the temperature from 180° C. to 255° C. over six hours and 40 minutes, and maintaining the temperature at 255° C. for five hours in a nitrogen atmosphere, and then, is cooled, and powdered aromatic polyester amide P1 is obtained.

A flow start temperature of the aromatic polyester amide P1 was 302° C. A melting point of aromatic polyester amide P1 was measured using a differential scanning calorimetry apparatus, and the result was 311° C. The dielectric loss tangent of the aromatic polyester amide P1 was 0.003.
P2: Commercially available epoxy resin (product name “jER-807”, manufactured by Mitsubishi Chemical Corporation)
P3: Commercially available cyanate resin (product name “CYTESTER P-201”, manufactured by Mitsubishi Gas Chemical Company, Inc.)

### <Curing Agent>

K1: Commercially available active ester resin (product name “EPICLON HPC-8000-65T”, manufactured by DIC Corporation)
K2: Commercially available phenol curing agent, aralkyl-type phenol resin (product name “MEH7800 series”, manufactured by MEIWA PLASTIC INDUSTRIES, LTD.)

### <Copper Foil>

M1: Product name “CF-T49A-DS-18”, manufactured by Fukuda Metal Foil & Powder Co., Ltd., average thickness: 18 μm (film formed on treatment surface side)

### <Film Formation>

The inorganic fillers and the resin shown in Table 1 were mixed at the contents (mass %) shown in Table 1, and dispersed with a beads mill to obtain a solution (dispersion liquid).

The obtained solution was fed to a slot die, and applied onto the copper foil shown in Table 1 by adjusting the flow rate such that the average thickness after drying was the thickness shown in Table 1. The solvent was removed from the coating film by hot air drying to obtain a polymer film (single-sided copper-clad laminated plate) having a copper layer. Furthermore, the single-sided copper-clad laminated plate was produced by performing a heat treatment of heating from 50° C. to 300° C. at 1° C./min and holding at 300° C. for 2 hours in a nitrogen atmosphere.

Do/Di was adjusted to the value shown in Table 1 under the conditions of the concentration of solid contents of the solution, the dispersion conditions, and the hot air drying conditions.

### [Preparation of Double-Sided Copper-Clad Laminated Plate]

Another copper foil shown in Table 1 was prepared, and the single-sided copper-clad laminated plate was laminated on the film side thereof using a laminator (product name “Vacuum laminator V-130”, manufactured by NIKKO MATERIALS Co., Ltd.) under the conditions of 140° C. and a laminating pressure of 0.4 MPa for 1 minute to obtain a precursor of a double-sided copper-clad laminated plate. Furthermore, using a heat sealer (product name “MP-SNL”, manufactured by Toyo Seiki Seisaku-sho, Ltd.), the obtained double-sided copper-clad laminated plate was heat-sealed under conditions of 320° C. and 4 MPa to prepare a double-sided copper-clad laminated plate.

### <<Evaluation>>

The produced single-sided copper-clad laminated plate and double-sided copper-clad laminated plate were measured and evaluated as shown below, and the results are shown in Table 1.

### <<Measuring Method>>

### [Particle Density]

The single-sided copper-clad laminated plate and a sample cut with a microtome were prepared, and the density (Di) of the inorganic filler in the in-plane direction and the density (Do) of the inorganic filler in the thickness direction were determined by a form observation using a scanning electron microscope, and the ratio (Do/Di) was further calculated, and the results are shown in Table 1.

### [Dielectric Characteristics]

The copper foil of the double-sided copper-clad laminated plate was removed with an aqueous solution of ferric chloride, and the film obtained by washing with pure water and drying was used for measurement.

A dielectric constant was measured by a resonance perturbation method at a frequency of 10 GHz. A 10 GHz cavity resonator (“CP531” manufactured by Kanto Electronics Application & Development Inc.) was connected to a network analyzer (“E8363B” manufactured by Agilent Technology), the film was inserted into the cavity resonator, and the relative permittivity and the dielectric loss tangent of the film were measured based on a change in resonance frequency for 96 hours before and after the insertion in an environment of a temperature of 25° C. and a humidity of 60% RH.

TABLE 1

| | Resin | | Curing agent | | Inorganic filler | | Copper | | | | Dielectric |
|---|---|---|---|---|---|---|---|---|---|---|---|
| | | % by | | % by | | % by | foil | Thickness | | Relative | loss |
| | Type | volume | Type | volume | Type | volume | Type | μm | Do/Di | permittivity | tangent |
| Example 1A | P1 | 80 | — | — | F1 | 20 | M1 | 50 | 0.9 | 22 | 0.008 |
| Example 2A | P1 | 80 | — | — | F1 | 20 | M1 | 50 | 0.5 | 8 | 0.008 |
| Example 3A | P1 | 60 | — | — | F1 | 40 | M1 | 50 | 0.7 | 19 | 0.012 |
| Comparative | P1 | 80 | — | — | F1 | 20 | M1 | 50 | 0.4 | 5 | 0.008 |
| Example 1 | | | | | | | | | | | |
| Example 4A | P1 | 60 | — | — | F2 | 40 | M1 | 50 | 0.7 | 19 | 0.002 |
| Example 5A | P1 | 60 | — | — | F3 | 40 | M1 | 50 | 0.7 | 16 | 0.003 |
| Example 6A | P1 | 60 | — | — | F4 | 40 | M1 | 50 | 0.7 | 18 | 0.003 |
| Example 7A | P2 | 34 | K1 | 26 | F2 | 40 | M1 | 50 | 0.7 | 19 | 0.004 |
| Example 8A | P2 | 34 | K2 | 26 | F2 | 40 | M1 | 50 | 0.7 | 21 | 0.006 |

From Table 1, it can be seen that the relative permittivity is increased by increasing Do/Di.

### [Antenna]

Two sets of the single-sided copper-clad laminated plates of Example 1A were prepared, and the film sides of the single-sided copper-clad laminated plates were compression-bonded using the above-described laminator and the heat sealer to produce a double-sided copper-clad laminated plate having a film thickness of 100 μm, and then the copper foil was patterned by a known subtractive method to produce a square microstrip antenna designed to have a resonance frequency of 10 GHZ. In addition, the single-sided copper-clad laminated plate of Comparative example 1 was processed in the same manner as the single-sided copper-clad laminated plate of Example 1A to produce a square microstrip antenna. The gains of the antennas of both examples were evaluated, and it was confirmed that Example 1A was excellent.

### [Metamaterial]

Two sets of the single-sided copper-clad laminated plates of Example 1A were prepared, and the film sides of the single-sided copper-clad laminated plates were compression-bonded using the above-described laminator and the heat sealer to produce a double-sided copper-clad laminated plate having a film thickness of 100 μm. Subsequently, the copper foil was patterned by a known subtractive method to form a metal pattern that selectively transmitted in the vicinity of 6 GHZ, and a metamaterial was produced. In addition, the single-sided copper-clad laminated plate of Comparative example 1 was processed in the same manner as the single-sided copper-clad laminated plate of Example 1A to produce a metamaterial. In a case where the frequency dependence of the transmission spectrum in the vicinity of 6 GHz was compared for the metamaterials of both examples, it was confirmed that Example 1A was excellent in selectivity.

In addition, two sets of the single-sided copper-clad laminated plates of Example 1A and a film obtained by etching and removing the copper foil of the single-sided copper-clad laminated plate were prepared, and a double-sided copper-clad laminated plate having a film thickness of 650 μm was produced using the above-described laminator and the heat sealer. Subsequently, one copper foil was patterned by a known subtractive method to form a metal pattern that resonated in the vicinity of 24 GHZ, and a metamaterial was produced. In addition, the single-sided copper-clad laminated plate of Comparative example 1 and the film from which the copper foil was removed were processed in the same manner as above to produce a metamaterial. In a case where the electromagnetic wave absorption spectra in the vicinity of 24 GHz were compared for the metamaterials of both examples, it was confirmed that Example 1A had stronger absorption.

### Examples 4 to 36

Details of each material used for preparing the film and the laminate are as follows. The same materials as in Example 1A and the like are omitted.

### <Inorganic Filler>

F2: Pulverized product of strontium titanate (average particle diameter: 1 μm, relative permittivity: 300, dielectric loss tangent: 0.0005)
F3: Pulverized product of titanium oxide (average particle diameter: 5 μm, relative permittivity: 90, dielectric loss tangent: 0.001)
F4: Pulverized product of calcium titanate (average particle diameter: 5 μm, relative permittivity: 200, dielectric loss tangent: 0.001)

### <Film Formation>

### Examples 4 to 8, Examples 13 to 19, Examples 24 to 30, and Examples 35 and 36

### -Layer B-

The solution of the aromatic polyester amide P1 was fed to a slot die, and applied onto the copper foil M1 by adjusting a flow rate such that the thickness of the layer B after drying was the thickness shown in Tables 2 to 4. The solvent was removed from the coating film by hot air drying to obtain a polymer film (single-sided copper-clad laminated plate) having a copper layer. Furthermore, the single-sided copper-clad laminated plate was produced by performing a heat treatment of heating from 50° C. to 300° C. at 1° C./min and holding at 300° C. for 2 hours in a nitrogen atmosphere. A plurality of recessed portions were formed on the obtained single-sided copper-clad laminated plate by laser processing.

In this case, the bottom surface of the recessed portion was the copper foil M1. In addition, the disposition and the size of the recessed portion were adjusted such that the width of the layer A and the distance between the layers A were the values shown in Tables 2 to 4.

As a result, a layer B was formed as a protruding portion on the copper foil M1.

### -Layer A-

The inorganic fillers and the resin shown in Tables 2 to 4 were mixed at the contents (mass %) shown in Tables 2 to 4, and dispersed with a beads mill to obtain a solution (dispersion liquid).

The obtained solution was allowed to flow between the layer B and the substrate film, and the solution was filled in the recessed portion by pressing the layer B and the substrate film with a laminator, and then the substrate film was peeled off and dried. The filling and the drying were repeated until the resin and the inorganic filler filled the recessed portion after drying. As a result, the plurality of layers A and the layer B were disposed in the same plane, and the plurality of layers A were disposed not to be in contact with each other.

Here, the substrate film is not particularly limited, and for example, a polyethylene terephthalate (PET) film is used.

### Examples 9 to 11, Examples 20 to 22, and Examples 31 to 33

### -Layer A and Layer B-

The layer A and the layer B were formed by the same method as in Example 1A.

### Layer C-

The solution of the aromatic polyester amide P1 was fed to a slot die, and applied onto the layer A and the layer B by adjusting a flow rate such that the thickness of the layer C after drying was the thickness shown in Tables 2 to 4. The solvent was removed from the coating film by hot air drying to obtain a polymer film (single-sided copper-clad laminated plate) having a copper layer. Furthermore, the layer C was formed on one surface of the layer A and the layer B by performing a heat treatment of heating from 50° C. to 300° C. at 1° C./min and holding at 300° C. for 2 hours in a nitrogen atmosphere.

As a result, the copper foil M1, “the layer A and the layer B”, and the layer C were formed in this order.

### Examples 12, 23, and 34

The layer C was formed on one surface of the layer A and the layer B by the same method as in Example 9.

As a result, the copper foil M1, “the layer A and the layer B”, and the layer C were formed in this order.

Next, the copper foil M1 was etched and removed with ferric chloride. Thereafter, the layer C was formed on “the layer A and the layer B” on the side opposite to the side on which the layer C was arranged, of the laminate in which “the layer A and the layer B” and the layer C were laminated in this order, in the same manner as in Example 9.

As a result, the layer C, “the layer A and the layer B”, and the layer C were formed in this order.

The copper foil M1 was overlapped on one layer C of the two layers C, and the laminating treatment was performed for 1 minute under the conditions of 140° C. and a laminating pressure of 0.4 MPa using a laminator (product name “Vacuum laminator V-130”, manufactured by Nikko-Materials Co., Ltd.) to obtain a precursor of a single-sided copper-clad laminated plate. Furthermore, using a heat sealer (product name “MP-SNL”, manufactured by Toyo Seiki Seisaku-sho, Ltd.), the obtained single-sided copper-clad laminated plate was heat-sealed under conditions of 320° C. and 4 MPa to prepare a single-sided copper-clad laminated plate.

In Tables 2 to 4, “single-sided” in the column of disposition of the layer C means that the layer C was formed on one surface of the layer A and the layer B. “Double-sided” means that the layer C was formed on both surfaces of the layer A and the layer B.

Do/Di was adjusted to the value shown in Tables 2 to 4 under the conditions of the concentration of solid contents of the solution, the dispersion conditions, and the hot air drying conditions.

[Preparation of Double-Sided Copper-Clad Laminated Plate]

Another copper foil M1 was prepared, and the single-sided copper-clad laminated plate was laminated on the film side thereof using a laminator (product name “Vacuum laminator V-130”, manufactured by NIKKO MATERIALS Co., Ltd.) under the conditions of 140° C. and a laminating pressure of 0.4 MPa for 1 minute to obtain a precursor of a double-sided copper-clad laminated plate. Furthermore, using a heat sealer (product name “MP-SNL”, manufactured by Toyo Seiki Seisaku-sho, Ltd.), the obtained double-sided copper-clad laminated plate was heat-sealed under conditions of 320° C. and 4 MPa to prepare a double-sided copper-clad laminated plate.

### <<Measurement>>

### [Width of Layer A]

The film was cut using a microtome in the thickness direction of the film. The cut surface was observed with an optical microscope or a scanning electron microscope, and the width of the layer A was measured. In addition, an average value of values measured at any 10 points was used as the width of the layer A.

[Distance between Layers A]

The film was cut using a microtome in the thickness direction of the film. The cut surface was observed with an optical microscope or a scanning electron microscope. A distance between two adjacent layers A was measured. An average value of values measured at any 10 points was used as the distance between layers A.

### <<Evaluation>>

### [Dielectric Characteristics]

The dielectric characteristics (relative permittivity and dielectric loss tangent) of the film were measured by the same method as in Example 1A. The evaluation was performed according to the following evaluation standard based on the measurement results.
A: The relative permittivity was 30 or more, and the dielectric loss tangent was 0.005 or less.
B: The relative permittivity was 10 or more and less than 30, or the dielectric loss tangent was more than 0.005 and 0.01 or less.
C: The relative permittivity was 5 or more and less than 10, or the dielectric loss tangent was more than 0.01 and 0.02 or less.

### [Mechanical Property (Brittleness)]

The obtained film was rolled into a cylindrical shape having a diameter of 50 mm, and the occurrence of cracks or breakage was visually observed. The evaluation standard was as follows.
A: No cracks occurred.
B: Cracks occurred.
C: Broke.

TABLE 2

| | | | | | | | | Layer A | | | | | | |
|---|---|---|---|---|---|---|---|---|---|---|---|---|---|---|
| | Film | | | | | | | | | | | | Distance | |
| | Resin | | Inorganic filler | | Copper | | | Resin | | Inorganic filler | | | between | |
| | | % by | | % by | foil | Thickness | | | % by | | % by | Width | layers A | Thickness |
| | Type | volume | Type | volume | Type | μm | Do/Di | Type | volume | Type | volume | μm | μm | μm |
| Example 4 | P1 | 30 | F2 | 60 | M1 | 30 | 0.7 | P1 | 10 | F2 | 90 | 300 | 50 | 30 |
| Example 5 | P1 | 35 | F2 | 50 | M1 | 30 | 0.7 | P1 | 20 | F2 | 80 | 300 | 50 | 30 |
| Example 6 | P1 | 55 | F2 | 45 | M1 | 30 | 0.7 | P1 | 30 | F2 | 70 | 300 | 50 | 30 |
| Example 7 | P1 | 60 | F2 | 30 | M1 | 30 | 0.7 | P1 | 50 | F2 | 50 | 300 | 50 | 30 |
| Example 8 | P1 | 65 | F2 | 25 | M1 | 30 | 0.7 | P1 | 60 | F2 | 40 | 300 | 50 | 30 |
| Example 9 | P1 | 40 | F2 | 60 | M1 | 31 | 0.7 | P1 | 10 | F2 | 90 | 300 | 50 | 30 |
| Example 10 | P1 | 45 | F2 | 55 | M1 | 33 | 0.7 | P1 | 10 | F2 | 90 | 300 | 50 | 30 |
| Example 11 | P1 | 50 | F2 | 50 | M1 | 35 | 0.7 | P1 | 10 | F2 | 90 | 300 | 50 | 30 |
| Example 12 | P1 | 40 | F2 | 60 | M1 | 31 | 0.7 | P1 | 10 | F2 | 90 | 300 | 50 | 30 |
| Example 13 | P1 | 60 | F2 | 40 | M1 | 30 | 0.5 | P1 | 10 | F2 | 90 | 250 | 100 | 30 |
| Example 14 | P1 | 30 | F2 | 70 | M1 | 30 | 0.8 | P1 | 10 | F2 | 90 | 330 | 20 | 30 |

| | Layer B | | | Layer C | | | | | |
|---|---|---|---|---|---|---|---|---|---|
| | Resin | | | Resin | | | | Evaluation | |
| | | % by | Thickness | | % by | Thickness | | Relative | |
| | Type | volume | μm | Type | volume | μm | Disposition | permittivity | Brittleness |
| Example 4 | P1 | 100 | 30 | — | — | — | — | A | B |
| Example 5 | P1 | 100 | 30 | — | — | — | — | A | B |
| Example 6 | P1 | 100 | 30 | — | — | — | — | B | A |
| Example 7 | P1 | 100 | 30 | — | — | — | — | B | A |
| Example 8 | P1 | 100 | 30 | — | — | — | — | C | A |
| Example 9 | P1 | 100 | 30 | P1 | 100 | 1 | | A | A |
| Example 10 | P1 | 100 | 30 | P1 | 100 | 3 | | B | A |
| Example 11 | P1 | 100 | 30 | P1 | 100 | 5 | | B | A |
| Example 12 | P1 | 100 | 30 | P1 | 100 | 0.5 + 0.5 | — | A | A |
| Example 13 | P1 | 100 | 30 | — | — | — | — | A | B |
| Example 14 | P1 | 100 | 30 | — | — | — | — | A | C |

TABLE 3

| | | | | | | | | Layer A | | | | | | |
|---|---|---|---|---|---|---|---|---|---|---|---|---|---|---|
| | Film | | | | | | | | | | | | Distance | |
| | Resin | | Inorganic filler | | Copper | | | Resin | | Inorganic filler | | | between | |
| | | % by | | % by | foil | Thickness | | | % by | | % by | Width | layers A | Thickness |
| | Type | volume | Type | volume | Type | μm | Do/Di | Type | volume | Type | volume | μm | μm | μm |
| Example 15 | P1 | 30 | F3 | 60 | M1 | 30 | 0.7 | P1 | 10 | F3 | 90 | 300 | 50 | 30 |
| Example 16 | P1 | 35 | F3 | 50 | M1 | 30 | 0.7 | P1 | 20 | F3 | 80 | 300 | 50 | 30 |
| Example 17 | P1 | 55 | F3 | 45 | M1 | 30 | 0.7 | P1 | 30 | F3 | 70 | 300 | 50 | 30 |
| Example 18 | P1 | 60 | F3 | 30 | M1 | 30 | 0.7 | P1 | 50 | F3 | 50 | 300 | 50 | 30 |
| Example 19 | P1 | 65 | F3 | 25 | M1 | 30 | 0.7 | P1 | 60 | F3 | 40 | 300 | 50 | 30 |
| Example 20 | P1 | 40 | F3 | 60 | M1 | 31 | 0.7 | P1 | 10 | F3 | 90 | 300 | 50 | 30 |
| Example 21 | P1 | 45 | F3 | 55 | M1 | 33 | 0.7 | P1 | 10 | F3 | 90 | 300 | 50 | 30 |
| Example 22 | P1 | 50 | F3 | 50 | M1 | 35 | 0.7 | P1 | 10 | F3 | 90 | 300 | 50 | 30 |
| Example 23 | P1 | 40 | F3 | 60 | M1 | 31 | 0.7 | P1 | 10 | F3 | 90 | 300 | 50 | 30 |
| Example 24 | P1 | 60 | F3 | 40 | M1 | 30 | 0.5 | P1 | 10 | F3 | 90 | 250 | 100 | 30 |
| Example 25 | P1 | 30 | F3 | 70 | M1 | 30 | 0.8 | P1 | 10 | F3 | 90 | 330 | 20 | 30 |

| | Layer B | | | Layer C | | | | | |
|---|---|---|---|---|---|---|---|---|---|
| | Resin | | | Resin | | | | Evaluation | |
| | | % by | Thickness | | % by | Thickness | | Relative | |
| | Type | volume | μm | Type | volume | μm | Disposition | permittivity | Brittleness |
| Example 15 | P1 | 100 | 30 | — | — | — | — | A | B |
| Example 16 | P1 | 100 | 30 | — | — | — | — | A | B |
| Example 17 | P1 | 100 | 30 | — | — | — | — | B | A |
| Example 18 | P1 | 100 | 30 | — | — | — | — | B | A |
| Example 19 | P1 | 100 | 30 | — | — | — | — | C | A |
| Example 20 | P1 | 100 | 30 | P1 | 100 | 1 | | A | A |
| Example 21 | P1 | 100 | 30 | P1 | 100 | 3 | | B | A |
| Example 22 | P1 | 100 | 30 | P1 | 100 | 5 | | B | A |
| Example 23 | P1 | 100 | 30 | P1 | 100 | 0.5 + 0.5 | | A | A |
| Example 24 | P1 | 100 | 30 | — | — | — | — | A | B |
| Example 25 | P1 | 100 | 30 | — | — | — | — | A | C |

TABLE 4

| | | | | | | | | Layer A | | | | | | |
|---|---|---|---|---|---|---|---|---|---|---|---|---|---|---|
| | Film | | | | | | | | | | | | Distance | |
| | Resin | | Inorganic filler | | Copper | | | Resin | | Inorganic filler | | | between | |
| | | % by | | % by | foil | Thickness | | | % by | | % by | Width | layers A | Thickness |
| | Type | volume | Type | volume | Type | μm | Do/Di | Type | volume | Type | volume | μm | μm | μm |
| Example 26 | P1 | 30 | F4 | 60 | M1 | 30 | 0.7 | P1 | 10 | F4 | 90 | 300 | 50 | 30 |
| Example 27 | P1 | 35 | F4 | 50 | M1 | 30 | 0.7 | P1 | 20 | F4 | 80 | 300 | 50 | 30 |
| Example 28 | P1 | 55 | F4 | 45 | M1 | 30 | 0.7 | P1 | 30 | F4 | 70 | 300 | 50 | 30 |
| Example 29 | P1 | 60 | F4 | 30 | M1 | 30 | 0.7 | P1 | 50 | F4 | 50 | 300 | 50 | 30 |
| Example 30 | P1 | 65 | F4 | 25 | M1 | 30 | 0.7 | P1 | 60 | F4 | 40 | 300 | 50 | 30 |
| Example 31 | P1 | 40 | F4 | 60 | M1 | 31 | 0.7 | P1 | 10 | F4 | 90 | 300 | 50 | 30 |
| Example 32 | P1 | 45 | F4 | 55 | M1 | 33 | 0.7 | P1 | 10 | F4 | 90 | 300 | 50 | 30 |
| Example 33 | P1 | 50 | F4 | 50 | M1 | 35 | 0.7 | P1 | 10 | F4 | 90 | 300 | 50 | 30 |
| Example 34 | P1 | 40 | F4 | 60 | M1 | 31 | 0.7 | P1 | 10 | F4 | 90 | 300 | 50 | 30 |
| Example 35 | P1 | 60 | F4 | 40 | M1 | 30 | 0.5 | P1 | 10 | F4 | 90 | 250 | 100 | 30 |
| Example 36 | P1 | 30 | F4 | 70 | M1 | 30 | 0.8 | P1 | 10 | F4 | 90 | 330 | 20 | 30 |

| | Layer B | | | Layer C | | | | | |
|---|---|---|---|---|---|---|---|---|---|
| | Resin | | | Resin | | | | Evaluation | |
| | | % by | Thickness | | % by | Thickness | | Relative | |
| | Type | volume | μm | Type | volume | μm | Disposition | permittivity | Brittleness |
| Example 26 | P1 | 100 | 30 | — | — | — | — | A | B |
| Example 27 | P1 | 100 | 30 | — | — | — | — | A | B |
| Example 28 | P1 | 100 | 30 | — | — | — | — | B | A |
| Example 29 | P1 | 100 | 30 | — | — | — | — | B | A |
| Example 30 | P1 | 100 | 30 | — | — | — | — | C | A |
| Example 31 | P1 | 100 | 30 | P1 | 100 | 1 | | A | A |
| Example 32 | P1 | 100 | 30 | P1 | 100 | 3 | | B | A |
| Example 33 | P1 | 100 | 30 | P1 | 100 | 5 | | B | A |
| Example 34 | P1 | 100 | 30 | P1 | 100 | 0.5 + 0.5 | | A | A |
| Example 35 | P1 | 100 | 30 | — | — | — | — | A | B |
| Example 36 | P1 | 100 | 30 | — | — | — | — | A | C |

As shown in Tables 2 to 4, it was found that the films of Examples 4 to 36 included an a high permittivity and a low dielectric loss tangent.

From the comparison between Example 7 and Example 8, the comparison between Example 18 and Example 19, and the comparison between Example 29 and Example 30, it was found that the dielectric characteristics were more excellent in a case where the content of the inorganic filler contained in the layer A was 50% by volume or more.

### Examples 37 to 69

Details of each material used for preparing the film and the laminate are as follows. The same materials as in Example 1A and the like are omitted.

### <Resin>

In Examples 59 to 69, P2 and K1 were used at a mass ratio of 1:1.

### <Film Formation>

### Examples 37 to 41, Examples 46 to 52, Examples 57 to 63, and Examples 68 and 69

### Layer B-

The resin shown in Tables 5 to 7 was fed to a slot die, and applied onto the copper foil M1 by adjusting a flow rate such that the thickness of the layer B after drying was the thickness shown in Tables 5 to 7. The solvent was removed from the coating film by hot air drying to obtain a polymer film (single-sided copper-clad laminated plate) having a copper layer. Furthermore, the single-sided copper-clad laminated plate was produced by performing a heat treatment of heating from 50° C. to 300° C. at 1° C./min and holding at 300° C. for 2 hours in a nitrogen atmosphere. A plurality of recessed portions were formed on the obtained single-sided copper-clad laminated plate by laser processing.

In this case, the bottom surface of the recessed portion was the copper foil M1.

In addition, the disposition and the size of the recessed portion were adjusted such that the width of the layer A and the distance between the layers A were the values shown in Tables 5 to 7.

As a result, a layer B was formed as a protruding portion on the copper foil M1.

### -Layer A-

The inorganic fillers and the resin shown in Tables 5 to 7 were mixed at the contents (mass %) shown in Tables 5 to 7, and dispersed with a beads mill to obtain a solution (dispersion liquid).

The obtained solution was allowed to flow between the layer B and the substrate film, and the solution was filled in the recessed portion by pressing the layer B and the substrate film with a laminator, and then the substrate film was peeled off and dried. The filling and the drying were repeated until the resin and the inorganic filler filled the recessed portion after drying. As a result, the plurality of layers A and the layer B were disposed in the same plane, and the plurality of layers A were disposed not to be in contact with each other.

Here, the substrate film is not particularly limited, and for example, a polyethylene terephthalate (PET) film is used.

### Examples 42 to 44, Examples 53 to 55, and Examples 64 to 66

### -Layer A and Layer B-

The layer A and the layer B were formed by the same method as in Example 1A.

### Layer C-

The resin shown in Tables 5 to 7 was fed to a slot die, and applied onto the layer A and the layer B by adjusting a flow rate such that the thickness of the layer C after drying was the thickness shown in Tables 5 to 7. The solvent was removed from the coating film by hot air drying to obtain a polymer film (single-sided copper-clad laminated plate) having a copper layer. Furthermore, the layer C was formed on one surface of the layer A and the layer B by performing a heat treatment of heating from 50° C. to 300° C. at 1° C./min and holding at 300° C. for 2 hours in a nitrogen atmosphere.

As a result, the copper foil M1, “the layer A and the layer B”, and the layer C were formed in this order.

### Examples 45, 56, and 67

The layer C was formed on one surface of the layer A and the layer B by the same method as in Example 9.

As a result, the copper foil M1, “the layer A and the layer B”, and the layer C were formed in this order.

Next, the copper foil M1 was etched and removed with ferric chloride. Thereafter, the layer C was formed on “the layer A and the layer B” on the side opposite to the side on which the layer C was arranged, of the laminate in which “the layer A and the layer B” and the layer C were laminated in this order, in the same manner as in Example 9.

As a result, the layer C, “the layer A and the layer B”, and the layer C were formed in this order.

The copper foil M1 was overlapped on one layer C of the two layers C, and the laminating treatment was performed for 1 minute under the conditions of 140° C. and a laminating pressure of 0.4 MPa using a laminator (product name “Vacuum laminator V-130”, manufactured by Nikko-Materials Co., Ltd.) to obtain a precursor of a single-sided copper-clad laminated plate. Furthermore, using a heat sealer (product name “MP-SNL”, manufactured by Toyo Seiki Seisaku-sho, Ltd.), the obtained single-sided copper-clad laminated plate was heat-sealed under conditions of 320° C. and 4 MPa to prepare a single-sided copper-clad laminated plate.

In Tables 5 to 7, “single-sided” in the column of disposition of the layer C means that the layer C was formed on one surface of the layer A and the layer B. “Double-sided” means that the layer C was formed on both surfaces of the layer A and the layer B.

Do/Di was adjusted to the value shown in Tables 5 to 7 under the conditions of the concentration of solid contents of the solution, the dispersion conditions, and the hot air drying conditions.

### [Preparation of Double-Sided Copper-Clad Laminated Plate]

Another copper foil M1 was prepared, and the single-sided copper-clad laminated plate was laminated on the film side thereof using a laminator (product name “Vacuum laminator V-130”, manufactured by NIKKO MATERIALS Co., Ltd.) under the conditions of 140° C. and a laminating pressure of 0.4 MPa for 1 minute to obtain a precursor of a double-sided copper-clad laminated plate. Furthermore, using a heat sealer (product name “MP-SNL”, manufactured by Toyo Seiki Seisaku-sho, Ltd.), the obtained double-sided copper-clad laminated plate was heat-sealed under conditions of 320° C. and 4 MPa to prepare a double-sided copper-clad laminated plate.

The width of the layer A and the distance between the layers A were measured by the same method as in Example 1A.

In addition, the dielectric characteristics and the brittleness were evaluated by the same method as in Example 1A.

TABLE 5

| | | | | | | | | Layer A | | | | | | |
|---|---|---|---|---|---|---|---|---|---|---|---|---|---|---|
| | Film | | | | | | | | | | | | Distance | |
| | Resin | | Inorganic filler | | Copper | | | Resin | | Inorganic filler | | | between | |
| | | % by | | % by | foil | Thickness | | | % by | | % by | Width | layers A | Thickness |
| | Type | volume | Typ | volume | Type | μm | Do/Di | Type | volume | Type | volume | μm | μm | μm |
| Example 37 | P1 + P2 | 30 | F2 | 60 | M1 | 30 | 0.7 | P1 | 10 | F2 | 90 | 300 | 50 | 30 |
| Example 38 | P1 + P2 | 35 | F2 | 50 | M1 | 30 | 0.7 | P1 | 20 | F2 | 80 | 300 | 50 | 30 |
| Example 39 | P1 + P2 | 55 | F2 | 45 | M1 | 30 | 0.7 | P1 | 30 | F2 | 70 | 300 | 50 | 30 |
| Example 40 | P1 + P2 | 60 | F2 | 30 | M1 | 30 | 0.7 | P1 | 50 | F2 | 50 | 300 | 50 | 30 |
| Example 41 | P1 + P2 | 65 | F2 | 25 | M1 | 30 | 0.7 | P1 | 60 | F2 | 40 | 300 | 50 | 30 |
| Example 42 | P1 + P2 | 40 | F2 | 60 | M1 | 31 | 0.7 | P1 | 10 | F2 | 90 | 300 | 50 | 30 |
| Example 43 | P1 + P2 | 45 | F2 | 55 | M1 | 33 | 0.7 | P1 | 10 | F2 | 90 | 300 | 50 | 30 |
| Example 44 | P1 + P2 | 50 | F2 | 50 | M1 | 35 | 0.7 | P1 | 10 | F2 | 90 | 300 | 50 | 30 |
| Example 45 | P1 + P2 | 40 | F2 | 60 | M1 | 31 | 0.7 | P1 | 10 | F2 | 90 | 300 | 50 | 30 |
| Example 46 | P1 + P2 | 60 | F2 | 40 | M1 | 30 | 0.5 | P1 | 10 | F2 | 90 | 250 | 100 | 30 |
| Example 47 | P1 + P2 | 30 | F2 | 70 | M1 | 30 | 0.8 | P1 | 10 | F2 | 90 | 330 | 20 | 30 |

| | Layer B | | | | Layer C | | | | | |
|---|---|---|---|---|---|---|---|---|---|---|
| | Resin | | | | Resin | | | | Evaluation | |
| | | % by | Width | Thickness | | % by | Thickness | | Relative | |
| | Type | volume | μm | μm | Type | volume | μm | Disposition | permittivity | Brittleness |
| Example 37 | P2 | 100 | 50 | 30 | — | — | — | — | A | B |
| Example 38 | P2 | 100 | 50 | 30 | — | — | — | — | A | B |
| Example 39 | P2 | 100 | 50 | 30 | — | — | — | — | B | A |
| Example 40 | P2 | 100 | 50 | 30 | — | — | — | — | B | A |
| Example 41 | P2 | 100 | 50 | 30 | — | — | — | — | C | A |
| Example 42 | P2 | 100 | 50 | 30 | P2 | 100 | 1 | | A | A |
| Example 43 | P2 | 100 | 50 | 30 | P2 | 100 | 3 | | B | A |
| Example 44 | P2 | 100 | 50 | 30 | P2 | 100 | 5 | | B | A |
| Example 45 | P2 | 100 | 50 | 30 | P2 | 100 | 0.5 + 0.5 | | A | A |
| Example 46 | P2 | 100 | 100 | 30 | — | — | — | — | A | B |
| Example 47 | P2 | 100 | 20 | 30 | — | — | — | — | A | C |

TABLE 6

| | | | | | | | | Layer A | | | | | | |
|---|---|---|---|---|---|---|---|---|---|---|---|---|---|---|
| | Film | | | | | | | | | | | | Distance | |
| | Resin | | Inorganic filler | | Copper | | | Resin | | Inorganic filler | | | between | |
| | | % by | | % by | foil | Thickness | | | % by | | % by | Width | layers A | Thickness |
| | Type | volume | Type | volume | Type | μm | Do/Di | Type | volume | Type | volume | μm | μm | μm |
| Example 48 | P1 + P3 | 30 | F2 | 60 | M1 | 30 | 0.7 | P1 | 10 | F3 | 90 | 300 | 50 | 30 |
| Example 49 | P1 + P3 | 35 | F2 | 50 | M1 | 30 | 0.7 | P1 | 20 | F3 | 80 | 300 | 50 | 30 |
| Example 50 | P1 + P3 | 55 | F2 | 45 | M1 | 30 | 0.7 | P1 | 30 | F3 | 70 | 300 | 50 | 30 |
| Example 51 | P1 + P3 | 60 | F2 | 30 | M1 | 30 | 0.7 | P1 | 50 | F3 | 50 | 300 | 50 | 30 |
| Example 52 | P1 + P3 | 65 | F2 | 25 | M1 | 30 | 0.7 | P1 | 60 | F3 | 40 | 300 | 50 | 30 |
| Example 53 | P1 + P3 | 40 | F2 | 60 | M1 | 31 | 0.7 | P1 | 10 | F3 | 90 | 300 | 50 | 30 |
| Example 54 | P1 + P3 | 45 | F2 | 55 | M1 | 33 | 0.7 | P1 | 10 | F3 | 90 | 300 | 50 | 30 |
| Example 55 | P1 + P3 | 50 | F2 | 50 | M1 | 35 | 0.7 | P1 | 10 | F3 | 90 | 300 | 50 | 30 |
| Example 56 | P1 + P3 | 40 | F2 | 60 | M1 | 31 | 0.7 | P1 | 10 | F3 | 90 | 300 | 50 | 30 |
| Example 57 | P1 + P3 | 60 | F2 | 40 | M1 | 30 | 0.5 | P1 | 10 | F3 | 90 | 250 | 100 | 30 |
| Example 58 | P1 + P3 | 30 | F2 | 70 | M1 | 30 | 0.8 | P1 | 10 | F3 | 90 | 330 | 20 | 30 |

| | Layer B | | | | Layer C | | | | | |
|---|---|---|---|---|---|---|---|---|---|---|
| | Resin | | | | Resin | | | | Evaluation | |
| | | % by | Width | Thickness | | % by | Thickness | | Relative | |
| | Type | volume | μm | μm | Type | volume | μm | Disposition | permittivity | Brittleness |
| Example 48 | P3 | 100 | 50 | 30 | — | — | — | — | A | B |
| Example 49 | P3 | 100 | 50 | 30 | — | — | — | — | A | B |
| Example 50 | P3 | 100 | 50 | 30 | — | — | — | — | B | A |
| Example 51 | P3 | 100 | 50 | 30 | — | — | — | — | B | A |
| Example 52 | P3 | 100 | 50 | 30 | — | — | — | — | C | A |
| Example 53 | P3 | 100 | 50 | 30 | P3 | 100 | 1 | | A | A |
| Example 54 | P3 | 100 | 50 | 30 | P3 | 100 | 3 | | B | A |
| Example 55 | P3 | 100 | 50 | 30 | P3 | 100 | 5 | | B | A |
| Example 56 | P3 | 100 | 50 | 30 | P3 | 100 | 0.5 + 0.5 | | A | A |
| Example 57 | P3 | 100 | 100 | 30 | — | — | — | — | A | B |
| Example 58 | P3 | 100 | 20 | 30 | — | — | — | — | A | C |

TABLE 7

| | | | | | | | | Layer A | | | | | | |
|---|---|---|---|---|---|---|---|---|---|---|---|---|---|---|
| | Film | | | | | | | | | | | | Distance | |
| | Resin | | Inorganic filler | | Copper | | | Resin | | Inorganic filler | | | between | |
| | | % by | | % by | foil | Thickness | | | % by | | % by | Width | layers A | Thickness |
| | Type | volume | Type | volume | Type | μm | Do/Di | Type | volume | Type | volume | μm | μm | μm |
| Example 59 | P1 + | 30 | F2 | 60 | M1 | 30 | 0.7 | P1 | 10 | F4 | 90 | 300 | 50 | 30 |
| | P2 + K1 | | | | | | | | | | | | | |
| Example 60 | P1 + | 35 | F2 | 50 | M1 | 30 | 0.7 | P1 | 20 | F4 | 80 | 300 | 50 | 30 |
| | P2 + K1 | | | | | | | | | | | | | |
| Example 61 | P1 + | 55 | F2 | 45 | M1 | 30 | 0.7 | P1 | 30 | F4 | 70 | 300 | 50 | 30 |
| | P2 + K1 | | | | | | | | | | | | | |
| Example 62 | P1 + | 60 | F2 | 30 | M1 | 30 | 0.7 | P1 | 50 | F4 | 50 | 300 | 50 | 30 |
| | P2 + K1 | | | | | | | | | | | | | |
| Example 63 | P1 + | 65 | F2 | 25 | M1 | 30 | 0.7 | P1 | 60 | F4 | 40 | 300 | 50 | 30 |
| | P2 + K1 | | | | | | | | | | | | | |
| Example 64 | P1 + | 40 | F2 | 60 | M1 | 31 | 0.7 | P1 | 10 | F4 | 90 | 300 | 50 | 30 |
| | P2 + K1 | | | | | | | | | | | | | |
| Example 65 | P1 + | 45 | F2 | 55 | M1 | 33 | 0.7 | P1 | 10 | F4 | 90 | 300 | 50 | 30 |
| | P2 + K1 | | | | | | | | | | | | | |
| Example 66 | P1 + | 50 | F2 | 50 | M1 | 35 | 0.7 | P1 | 10 | F4 | 90 | 300 | 50 | 30 |
| | P2 + K1 | | | | | | | | | | | | | |
| Example 67 | P1 + | 40 | F2 | 60 | M1 | 31 | 0.7 | P1 | 10 | F4 | 90 | 300 | 50 | 30 |
| | P2 + K1 | | | | | | | | | | | | | |
| Example 68 | P1 + | 60 | F2 | 40 | M1 | 30 | 0.5 | P1 | 10 | F4 | 90 | 250 | 100 | 30 |
| | P2 + K1 | | | | | | | | | | | | | |
| Example 69 | P1 + | 30 | F2 | 70 | M1 | 30 | 0.8 | P1 | 10 | F4 | 90 | 330 | 20 | 30 |
| | P2 + K1 | | | | | | | | | | | | | |

| | Layer B | | | | Layer C | | | | | |
|---|---|---|---|---|---|---|---|---|---|---|
| | Resin | | | | Resin | | | | Evaluation | |
| | | % by | Width | Thickness | | % by | Thickness | | Relative | |
| | Type | volume | μm | μm | Type | volume | μm | Disposition | permittivity | Brittleness |
| Example 59 | P2 + K1 | 100 | 50 | 30 | — | — | — | — | A | B |
| Example 60 | P2 + K1 | 100 | 50 | 30 | — | — | — | — | A | B |
| Example 61 | P2 + K1 | 100 | 50 | 30 | — | — | — | — | B | A |
| Example 62 | P2 + K1 | 100 | 50 | 30 | — | — | — | — | B | A |
| Example 63 | P2 + K1 | 100 | 50 | 30 | — | — | — | — | C | A |
| Example 64 | P2 + K1 | 100 | 50 | 30 | K1 | 100 | 1 | | A | A |
| Example 65 | P2 + K1 | 100 | 50 | 30 | K1 | 100 | 3 | | B | A |
| Example 66 | P2 + K1 | 100 | 50 | 30 | K1 | 100 | 5 | | B | A |
| Example 67 | P2 + K1 | 100 | 50 | 30 | K1 | 100 | 0.5 + 0.5 | | A | A |
| Example 68 | P2 + K1 | 100 | 100 | 30 | — | — | — | — | A | B |
| Example 69 | P2 + K1 | 100 | 20 | 30 | — | — | — | — | A | C |

As shown in Tables 5 to 7, it was found that the films of Examples 37 to 69 included an a high permittivity and a low dielectric loss tangent.

From the comparison between Example 40 and Example 41, the comparison between Example 51 and Example 52, and the comparison between Example 62 and Example 63, it was found that the dielectric characteristics were more excellent in a case where the content of the inorganic filler contained in the layer A was 50% by volume or more.

### Examples 70 to 102

Details of each material used for preparing the film and the laminate are as follows. The same materials as in Example 1A and the like are omitted.

### <Film Formation>

### Examples 70 to 74, Examples 79 to 85, Examples 90 to 96, and Examples 101 and 102

### -Layer B-

The resin shown in Tables 8 to 10 was fed to a slot die, and applied onto the copper foil M1 by adjusting a flow rate such that the thickness of the layer B after drying was the thickness shown in Tables 8 to 10. The solvent was removed from the coating film by hot air drying to obtain a polymer film (single-sided copper-clad laminated plate) having a copper layer. Furthermore, the single-sided copper-clad laminated plate was produced by performing a heat treatment of heating from 50° C. to 300° C. at 1° C./min and holding at 300° C. for 2 hours in a nitrogen atmosphere. A plurality of recessed portions were formed on the obtained single-sided copper-clad laminated plate by laser processing.

In this case, the bottom surface of the recessed portion was the copper foil M1. In addition, the disposition and the size of the recessed portion were adjusted such that the width of the layer A and the distance between the layers A were the values shown in Tables 8 to 10.

As a result, a layer B was formed as a protruding portion on the copper foil M1.

### -Layer A-

The fillers and the resin shown in Tables 8 to 10 were mixed at the contents (mass %) shown in Tables 8 to 10, and dispersed with a beads mill to obtain a solution (dispersion liquid).

The obtained solution was allowed to flow between the layer B and the substrate film, and the solution was filled in the recessed portion by pressing the layer B and the substrate film with a laminator, and then the substrate film was peeled off and dried. The filling and the drying were repeated until the resin and the inorganic filler filled the recessed portion after drying. As a result, the plurality of layers A and the layer B were disposed in the same plane, and the plurality of layers A were disposed not to be in contact with each other.

Here, the substrate film is not particularly limited, and for example, a polyethylene terephthalate (PET) film is used.

### Examples 75 to 77, Examples 86 to 88, and Examples 97 to 99

### -Layer A and Layer B-

The layer A and the layer B were formed by the same method as in Example 1A.

### -Layer C-

The resin shown in Tables 8 to 10 was fed to a slot die, and applied onto the layer A and the layer B by adjusting a flow rate such that the thickness of the layer C after drying was the thickness shown in Tables 8 to 10. The solvent was removed from the coating film by hot air drying to obtain a polymer film (single-sided copper-clad laminated plate) having a copper layer. Furthermore, the layer C was formed on one surface of the layer A and the layer B by performing a heat treatment of heating from 50° C. to 300° C. at 1° C./min and holding at 300° C. for 2 hours in a nitrogen atmosphere.

As a result, the copper foil M1, “the layer A and the layer B”, and the layer C were formed in this order.

### Examples 78, 89, and 100

The layer C was formed on one surface of the layer A and the layer B by the same method as in Example 9.

As a result, the copper foil M1, “the layer A and the layer B”, and the layer C were formed in this order.

Next, the copper foil M1 was etched and removed with ferric chloride. Thereafter, the layer C was formed on “the layer A and the layer B” on the side opposite to the side on which the layer C was arranged, of the laminate in which “the layer A and the layer B” and the layer C were laminated in this order, in the same manner as in Example 9.

As a result, the layer C, “the layer A and the layer B”, and the layer C were formed in this order.

The copper foil M1 was overlapped on one layer C of the two layers C, and the laminating treatment was performed for 1 minute under the conditions of 140° C. and a laminating pressure of 0.4 MPa using a laminator (product name “Vacuum laminator V-130”, manufactured by Nikko-Materials Co., Ltd.) to obtain a precursor of a single-sided copper-clad laminated plate. Furthermore, using a heat sealer (product name “MP-SNL”, manufactured by Toyo Seiki Seisaku-sho, Ltd.), the obtained single-sided copper-clad laminated plate was heat-sealed under conditions of 320° C. and 4 MPa to prepare a single-sided copper-clad laminated plate.

In Tables 8 to 10, “single-sided” in the column of disposition of the layer C means that the layer C was formed on one surface of the layer A and the layer B. “Double-sided” means that the layer C was formed on both surfaces of the layer A and the layer B.

Do/Di was adjusted to the value shown in Tables 8 to 10 under the conditions of the concentration of solid contents of the solution, the dispersion conditions, and the hot air drying conditions.

### [Preparation of Double-Sided Copper-Clad Laminated Plate]

Another copper foil M1 was prepared, and the single-sided copper-clad laminated plate was laminated on the film side thereof using a laminator (product name “Vacuum laminator V-130”, manufactured by NIKKO MATERIALS Co., Ltd.) under the conditions of 140° C. and a laminating pressure of 0.4 MPa for 1 minute to obtain a precursor of a double-sided copper-clad laminated plate. Furthermore, using a heat sealer (product name “MP-SNL”, manufactured by Toyo Seiki Seisaku-sho, Ltd.), the obtained double-sided copper-clad laminated plate was heat-sealed under conditions of 320° C. and 4 MPa to prepare a double-sided copper-clad laminated plate.

The width of the layer A and the distance between the layers A were measured by the same method as in Example 1A.

### <<Evaluation>>

### [Dielectric Characteristics]

The dielectric characteristics (relative permittivity and dielectric loss tangent) of the film were measured by the same method as in Example 1A. The evaluation was performed according to the following evaluation standard based on the measurement results.
A: The relative permittivity was 2 or less, and the dielectric loss tangent was 0.005 or less.
B: The relative permittivity was more than 2 and 3 or less, or the dielectric loss tangent was more than 0.005 and 0.01 or less.
C: The relative permittivity was more than 3 and 5 or less, or the dielectric loss tangent was more than 0.01 and 0.02 or less.

### [Mechanical Property (Brittleness)]

The obtained film was rolled into a cylindrical shape having a diameter of 50 mm, and the occurrence of cracks or breakage was visually observed. The evaluation standard was as follows.
A: No cracks occurred.
B: Cracks occurred.
C: Broke.

TABLE 8

| | | | | | | | | Layer A | | | | | | |
|---|---|---|---|---|---|---|---|---|---|---|---|---|---|---|
| | Film | | | | | | | | | | | | Distance | |
| | Resin | | Inorganic filler | | Copper | | | Resin | | Inorganic filler | | | between | |
| | | % by | | % by | foil | Thickness | | | % by | | % by | Width | layers A | Thickness |
| | Type | volume | Type | volume | Type | μm | Do/Di | Type | volume | Type | volume | μm | μm | μm |
| Example 70 | P1 | 30 | F5 | 60 | M1 | 30 | 0.7 | P1 | 10 | F5 | 90 | 300 | 50 | 30 |
| Example 71 | P1 | 35 | F5 | 50 | M1 | 30 | 0.7 | P1 | 20 | F5 | 80 | 300 | 50 | 30 |
| Example 72 | P1 | 55 | F5 | 45 | M1 | 30 | 0.7 | P1 | 30 | F5 | 70 | 300 | 50 | 30 |
| Example 73 | P1 | 60 | F5 | 30 | M1 | 30 | 0.7 | P1 | 50 | F5 | 50 | 300 | 50 | 30 |
| Example 74 | P1 | 65 | F5 | 25 | M1 | 30 | 0.7 | P1 | 60 | F5 | 40 | 300 | 50 | 30 |
| Example 75 | P1 | 40 | F5 | 60 | M1 | 31 | 0.7 | P1 | 10 | F5 | 90 | 300 | 50 | 30 |
| Example 76 | P1 | 45 | F5 | 55 | M1 | 33 | 0.7 | P1 | 10 | F5 | 90 | 300 | 50 | 30 |
| Example 77 | P1 | 50 | F5 | 50 | M1 | 35 | 0.7 | P1 | 10 | F5 | 90 | 300 | 50 | 30 |
| Example 78 | P1 | 40 | F5 | 60 | M1 | 31 | 0.7 | P1 | 10 | F5 | 90 | 300 | 50 | 30 |
| Example 79 | P1 | 60 | F5 | 40 | M1 | 30 | 0.5 | P1 | 10 | F5 | 90 | 250 | 100 | 30 |
| Example 80 | P1 | 30 | F5 | 70 | M1 | 30 | 0.8 | P1 | 10 | F5 | 90 | 330 | 20 | 30 |

| | Layer B | | | | Layer C | | | | | |
|---|---|---|---|---|---|---|---|---|---|---|
| | Resin | | | | Resin | | | | Evaluation | |
| | | % by | Width | Thickness | | % by | Thickness | | Relative | |
| | Type | volume | μm | μm | Type | volume | μm | Disposition | permittivity | Brittleness |
| Example 70 | P1 | 100 | 50 | 30 | — | — | — | — | A | B |
| Example 71 | P1 | 100 | 50 | 30 | — | — | — | — | A | B |
| Example 72 | P1 | 100 | 50 | 30 | — | — | — | — | B | A |
| Example 73 | P1 | 100 | 50 | 30 | — | — | — | — | B | A |
| Example 74 | P1 | 100 | 50 | 30 | — | — | — | — | B | A |
| Example 75 | P1 | 100 | 50 | 30 | P1 | 100 | 1 | | A | A |
| Example 76 | P1 | 100 | 50 | 30 | P1 | 100 | 3 | | A | A |
| Example 77 | P1 | 100 | 50 | 30 | P1 | 100 | 5 | | A | A |
| Example 78 | P1 | 100 | 50 | 30 | P1 | 100 | 0.5 + 0.5 | | A | A |
| Example 79 | P1 | 100 | 100 | 30 | — | — | — | — | B | B |
| Example 80 | P1 | 100 | 20 | 30 | — | — | — | — | A | C |

TABLE 9

| | | | | | | | | Layer A | | | | | | |
|---|---|---|---|---|---|---|---|---|---|---|---|---|---|---|
| | Film | | | | | | | | | | | | Distance | |
| | Resin | | Inorganic filler | | Copper | | | Resin | | Inorganic filler | | | between | |
| | | % by | | % by | foil | Thickness | | | % by | | % by | Width | layers A | Thickness |
| | Type | volume | Type | volume | Type | μm | Do/Di | Type | volume | Type | volume | μm | μm | μm |
| Example 81 | P1 | 30 | F6 | 60 | M1 | 30 | 0.7 | P1 | 10 | F6 | 90 | 300 | 50 | 30 |
| Example 82 | P1 | 35 | F6 | 50 | M1 | 30 | 0.7 | P1 | 20 | F6 | 80 | 300 | 50 | 30 |
| Example 83 | P1 | 55 | F6 | 45 | M1 | 30 | 0.7 | P1 | 30 | F6 | 70 | 300 | 50 | 30 |
| Example 84 | P1 | 60 | F6 | 30 | M1 | 30 | 0.7 | P1 | 50 | F6 | 50 | 300 | 50 | 30 |
| Example 85 | P1 | 65 | F6 | 25 | M1 | 30 | 0.7 | P1 | 60 | F6 | 40 | 300 | 50 | 30 |
| Example 86 | P1 | 40 | F6 | 60 | M1 | 31 | 0.7 | P1 | 10 | F6 | 90 | 300 | 50 | 30 |
| Example 87 | P1 | 45 | F6 | 55 | M1 | 33 | 0.7 | P1 | 10 | F6 | 90 | 300 | 50 | 30 |
| Example 88 | P1 | 50 | F6 | 50 | M1 | 35 | 0.7 | P1 | 10 | F6 | 90 | 300 | 50 | 30 |
| Example 89 | P1 | 40 | F6 | 60 | M1 | 31 | 0.7 | P1 | 10 | F6 | 90 | 300 | 50 | 30 |
| Example 90 | P1 | 60 | F6 | 40 | M1 | 30 | 0.5 | P1 | 10 | F6 | 90 | 250 | 100 | 30 |
| Example 91 | P1 | 30 | F6 | 70 | M1 | 30 | 0.8 | P1 | 10 | F6 | 90 | 330 | 20 | 30 |

| | Layer B | | | | Layer C | | | | | |
|---|---|---|---|---|---|---|---|---|---|---|
| | Resin | | | | Resin | | | | Evaluation | |
| | | % by | Width | Thickness | | % by | Thickness | | Relative | |
| | Type | volume | μm | μm | Type | volume | μm | Disposition | permittivity | Brittleness |
| Example 81 | P1 | 100 | 50 | 30 | — | — | — | — | B | B |
| Example 82 | P1 | 100 | 50 | 30 | — | — | — | — | B | B |
| Example 83 | P1 | 100 | 50 | 30 | — | — | — | — | B | A |
| Example 84 | P1 | 100 | 50 | 30 | — | — | — | — | B | A |
| Example 85 | P1 | 100 | 50 | 30 | — | — | — | — | C | A |
| Example 86 | P1 | 100 | 50 | 30 | P1 | 100 | 1 | | B | A |
| Example 87 | P1 | 100 | 50 | 30 | P1 | 100 | 3 | | B | A |
| Example 88 | P1 | 100 | 50 | 30 | P1 | 100 | 5 | | B | A |
| Example 89 | P1 | 100 | 50 | 30 | P1 | 100 | 0.5 + 0.5 | | B | A |
| Example 90 | P1 | 100 | 100 | 30 | — | — | — | — | B | B |
| Example 91 | P1 | 100 | 20 | 30 | — | — | — | — | B | C |

TABLE 10

| | | | | | | | | Layer A | | | | | | |
|---|---|---|---|---|---|---|---|---|---|---|---|---|---|---|
| | Film | | | | | | | | | | | | Distance | |
| | Resin | | Inorganic filler | | Copper | | | Resin | | Inorganic filler | | | between | |
| | | % by | | % by | foil | Thickness | | | % by | | % by | Width | layers A | Thickness |
| | Type | volume | Type | volume | Type | μm | Do/Di | Type | volume | Type | volume | μm | μm | μm |
| Example 92 | P1 | 30 | F7 | 60 | M1 | 30 | 0.7 | P1 | 10 | F7 | 90 | 300 | 50 | 30 |
| Example 93 | P1 | 35 | F7 | 50 | M1 | 30 | 0.7 | P1 | 20 | F7 | 80 | 300 | 50 | 30 |
| Example 94 | P1 | 55 | F7 | 45 | M1 | 30 | 0.7 | P1 | 30 | F7 | 70 | 300 | 50 | 30 |
| Example 95 | P1 | 60 | F7 | 30 | M1 | 30 | 0.7 | P1 | 50 | F7 | 50 | 300 | 50 | 30 |
| Example 96 | P1 | 65 | F7 | 25 | M1 | 30 | 0.7 | P1 | 60 | F7 | 40 | 300 | 50 | 30 |
| Example 97 | P1 | 40 | F7 | 60 | M1 | 31 | 0.7 | P1 | 10 | F7 | 90 | 300 | 50 | 30 |
| Example 98 | P1 | 45 | F7 | 55 | M1 | 33 | 0.7 | P1 | 10 | F7 | 90 | 300 | 50 | 30 |
| Example 99 | P1 | 50 | F7 | 50 | M1 | 35 | 0.7 | P1 | 10 | F7 | 90 | 300 | 50 | 30 |
| Example 100 | P1 | 40 | F7 | 60 | M1 | 31 | 0.7 | P1 | 10 | F7 | 90 | 300 | 50 | 30 |
| Example 101 | P1 | 60 | F7 | 40 | M1 | 30 | 0.5 | P1 | 10 | F7 | 90 | 250 | 100 | 30 |
| Example 102 | P1 | 30 | F7 | 70 | M1 | 30 | 0.8 | P1 | 10 | F7 | 90 | 330 | 20 | 30 |

| | Layer B | | | | Layer C | | | | | |
|---|---|---|---|---|---|---|---|---|---|---|
| | Resin | | | | Resin | | | | Evaluation | |
| | | % by | Width | Thickness | | % by | Thickness | | Relative | |
| | Type | volume | μm | μm | Type | volume | μm | Disposition | permittivity | Brittleness |
| Example 92 | P1 | 100 | 50 | 30 | — | — | — | — | B | B |
| Example 93 | P1 | 100 | 50 | 30 | — | — | — | — | B | B |
| Example 94 | P1 | 100 | 50 | 30 | — | — | — | — | B | A |
| Example 95 | P1 | 100 | 50 | 30 | — | — | — | — | C | A |
| Example 96 | P1 | 100 | 50 | 30 | — | — | — | — | C | A |
| Example 97 | P1 | 100 | 50 | 30 | P1 | 100 | 1 | | B | A |
| Example 98 | P1 | 100 | 50 | 30 | P1 | 100 | 3 | | B | A |
| Example 99 | P1 | 100 | 50 | 30 | P1 | 100 | 5 | | B | A |
| Example 100 | P1 | 100 | 50 | 30 | P1 | 100 | 0.5 + 0.5 | | B | A |
| Example 101 | P1 | 100 | 100 | 30 | — | — | — | — | B | B |
| Example 102 | P1 | 100 | 20 | 30 | — | — | — | — | B | C |

As shown in Tables 8 to 10, the films of Examples 70 to 102 included a filler and a resin, and had a ratio (Do/Di) of 0.5 or more, and thus the relative permittivity could achieve 1 to 5.

### Examples 103 to 126

### -Layer A and Layer B-

The layer A and the layer B were formed by the same method as in Example 1A.

### -Layer C-

The resin shown in Table 11 was fed to a slot die, and applied onto the layer A and the layer B by adjusting a flow rate such that the thickness of the layer C after drying was the thickness shown in Tables 8 to 10. The solvent was removed from the coating film by hot air drying to obtain a polymer film (single-sided copper-clad laminated plate) having a copper layer. Furthermore, the layer C was formed on one surface of the layer A and the layer B by performing a heat treatment of heating from 50° C. to 300° C. at 1° C./min and holding at 300° C. for 2 hours in a nitrogen atmosphere.

As a result, the copper foil M1, “the layer A and the layer B”, and the layer C were formed in this order.

The layer C was formed on one surface of the layer A and the layer B by the same method as in Example 9.

As a result, the copper foil M1, “the layer A and the layer B”, and the layer C were formed in this order.

Next, the copper foil M1 was etched and removed with ferric chloride. Thereafter, the layer C was formed on “the layer A and the layer B” on the side opposite to the side on which the layer C was arranged, of the laminate in which “the layer A and the layer B” and the layer C were laminated in this order, in the same manner as in Example 9.

As a result, the layer C, “the layer A and the layer B”, and the layer C were formed in this order.

The copper foil M1 was overlapped on one layer C of the two layers C, and the laminating treatment was performed for 1 minute under the conditions of 140° C. and a laminating pressure of 0.4 MPa using a laminator (product name “Vacuum laminator V-130”, manufactured by Nikko-Materials Co., Ltd.) to obtain a precursor of a single-sided copper-clad laminated plate. Furthermore, using a heat sealer (product name “MP-SNL”, manufactured by Toyo Seiki Seisaku-sho, Ltd.), the obtained single-sided copper-clad laminated plate was heat-sealed under conditions of 320° C. and 4 MPa to prepare a single-sided copper-clad laminated plate.

In Table 11, “single-sided” in the column of disposition of the layer C means that the layer C was formed on one surface of the layer A and the layer B. “Double-sided” means that the layer C was formed on both surfaces of the layer A and the layer B.

Do/Di was adjusted to the value shown in Table 11 under the conditions of the concentration of solid contents of the solution, the dispersion conditions, and the hot air drying conditions.

### [Preparation of Double-Sided Copper-Clad Laminated Plate]

Another copper foil M1 was prepared, and the single-sided copper-clad laminated plate was laminated on the film side thereof using a laminator (product name “Vacuum laminator V-130”, manufactured by NIKKO MATERIALS Co., Ltd.) under the conditions of 140° C. and a laminating pressure of 0.4 MPa for 1 minute to obtain a precursor of a double-sided copper-clad laminated plate. Furthermore, using a heat sealer (product name “MP-SNL”, manufactured by Toyo Seiki Seisaku-sho, Ltd.), the obtained double-sided copper-clad laminated plate was heat-sealed under conditions of 320° C. and 4 MPa to prepare a double-sided copper-clad laminated plate.

The width of the layer A, the distance between the layers A, and the dielectric characteristics were measured by the same method as in Example 9.

The transmission loss was measured for a microstrip line formed on one surface of the double-sided copper-clad laminated plate by performing resist coating, mask exposure, development, and copper etching. The evaluation was performed according to the following evaluation standard based on the measurement results.
A: −0.24 dB or more.
B: Less than −0.24 dB and −0.25 dB or more.
C: Less than −0.25 dB.

TABLE 11

| | Film | | | | | | | | Layer A | | | | | |
|---|---|---|---|---|---|---|---|---|---|---|---|---|---|---|
| | Resin | | Inorganic filler | | Copper | | Surface | | Resin | | Inorganic filler | | | |
| | | % by | | % by | foil | Thickness | roughness | | | % by | | % by | Width | Thickness |
| | Type | volume | Type | volume | Type | μm | μm | Do/Di | Type | volume | Type | volume | μm | μm |
| Example | P1 | 30 | F2 | 60 | M1 | 30 | 6 | 0.7 | P1 | 10 | F2 | 90 | 300 | 30 |
| 103 | | | | | | | | | | | | | | |
| Example | P1 | 35 | F2 | 50 | M1 | 30 | 5 | 0.7 | P1 | 20 | F2 | 80 | 300 | 30 |
| 104 | | | | | | | | | | | | | | |
| Example | P1 | 30 | F2 | 60 | M1 | 31 | 4 | 0.7 | P1 | 10 | F2 | 90 | 300 | 30 |
| 105 | | | | | | | | | | | | | | |
| Example | P1 | 35 | F2 | 50 | M1 | 31 | 3 | 0.7 | P1 | 20 | F2 | 80 | 300 | 30 |
| 106 | | | | | | | | | | | | | | |
| Example | P1 | 30 | F2 | 60 | M1 | 32 | 1 | 0.7 | P1 | 10 | F2 | 90 | 300 | 30 |
| 107 | | | | | | | | | | | | | | |
| Example | P1 | 35 | F2 | 50 | M1 | 32 | 1 | 0.7 | P1 | 20 | F2 | 80 | 300 | 30 |
| 108 | | | | | | | | | | | | | | |
| Example | P1 + P2 | 30 | F2 | 60 | M1 | 30 | 6 | 0.7 | P1 | 10 | F2 | 90 | 300 | 30 |
| 109 | | | | | | | | | | | | | | |
| Example | P1 + P2 | 35 | F2 | 50 | M1 | 30 | 5 | 0.7 | P1 | 20 | F2 | 80 | 300 | 30 |
| 110 | | | | | | | | | | | | | | |
| Example | P1 + P2 | 30 | F2 | 60 | M1 | 31 | 4 | 0.7 | P1 | 10 | F2 | 90 | 300 | 30 |
| 111 | | | | | | | | | | | | | | |
| Example | P1 + P2 | 35 | F2 | 50 | M1 | 31 | 3 | 0.7 | P1 | 20 | F2 | 80 | 300 | 30 |
| 112 | | | | | | | | | | | | | | |
| Example | P1 + P2 | 30 | F2 | 60 | M1 | 32 | 1 | 0.7 | P1 | 10 | F2 | 90 | 300 | 30 |
| 113 | | | | | | | | | | | | | | |
| Example | P1 + P2 | 35 | F2 | 50 | M1 | 32 | 1 | 0.7 | P1 | 20 | F2 | 80 | 300 | 30 |
| 114 | | | | | | | | | | | | | | |
| Example | P1 + P3 | 30 | F2 | 60 | M1 | 30 | 6 | 0.7 | P1 | 10 | F2 | 90 | 300 | 30 |
| 115 | | | | | | | | | | | | | | |
| Example | P1 + P3 | 35 | F2 | 50 | M1 | 30 | 5 | 0.7 | P1 | 20 | F2 | 80 | 300 | 30 |
| 116 | | | | | | | | | | | | | | |
| Example | P1 + P3 | 30 | F2 | 60 | M1 | 31 | 4 | 0.7 | P1 | 10 | F2 | 90 | 300 | 30 |
| 117 | | | | | | | | | | | | | | |
| Example | P1 + P3 | 35 | F2 | 50 | M1 | 31 | 3 | 0.7 | P1 | 20 | F2 | 80 | 300 | 30 |
| 118 | | | | | | | | | | | | | | |
| Example | P1 + P3 | 30 | F2 | 60 | M1 | 32 | 1 | 0.7 | P1 | 10 | F2 | 90 | 300 | 30 |
| 119 | | | | | | | | | | | | | | |
| Example | P1 + P3 | 35 | F2 | 50 | M1 | 32 | 1 | 0.7 | P1 | 20 | F2 | 80 | 300 | 30 |
| 120 | | | | | | | | | | | | | | |
| Example | P1 + | 30 | F2 | 60 | M1 | 30 | 6 | 0.7 | P1 | 10 | F2 | 90 | 300 | 30 |
| 121 | P2 + K1 | | | | | | | | | | | | | |
| Example | P1 + | 35 | F2 | 50 | M1 | 30 | 5 | 0.7 | P1 | 20 | F2 | 80 | 300 | 30 |
| 122 | P2 + K1 | | | | | | | | | | | | | |
| Example | P1 + | 30 | F2 | 60 | M1 | 31 | 4 | 0.7 | P1 | 10 | F2 | 90 | 300 | 30 |
| 123 | P2 + K1 | | | | | | | | | | | | | |
| Example | P1 + | 35 | F2 | 50 | M1 | 31 | 3 | 0.7 | P1 | 20 | F2 | 80 | 300 | 30 |
| 124 | P2 + K1 | | | | | | | | | | | | | |
| Example | P1 + | 30 | F2 | 60 | M1 | 32 | 1 | 0.7 | P1 | 10 | F2 | 90 | 300 | 30 |
| 125 | P2 + K1 | | | | | | | | | | | | | |
| Example | P1 + | 35 | F2 | 50 | M1 | 32 | 1 | 0.7 | P1 | 20 | F2 | 80 | 300 | 30 |
| 126 | P2 + K1 | | | | | | | | | | | | | |

| | Layer B | | | | Layer C | | | | | | |
|---|---|---|---|---|---|---|---|---|---|---|---|
| | Resin | | | | Resin | | | | Evaluation | | |
| | | % by | Width | Thickness | | % by | Thickness | | Relative | | Transmission |
| | Type | volume | μm | μm | Type | volume | μm | Disposition | permittivity | Brittleness | loss |
| Example | P1 | 100 | 50 | 30 | — | — | — | — | A | B | C |
| 103 | | | | | | | | | | | |
| Example | P1 | 100 | 50 | 30 | — | — | — | — | A | B | B |
| 104 | | | | | | | | | | | |
| Example | P1 | 100 | 50 | 30 | P1 | 100 | 0.5 + 0.5 | | A | A | B |
| 105 | | | | | | | | | | | |
| Example | P1 | 100 | 50 | 30 | P1 | 100 | 0.5 + 0.5 | | A | A | A |
| 106 | | | | | | | | | | | |
| Example | P1 | 100 | 50 | 30 | P1 | 100 | 1 + 1 | | B | A | A |
| 107 | | | | | | | | | | | |
| Example | P1 | 100 | 50 | 30 | P1 | 100 | 1 + 1 | | B | A | A |
| 108 | | | | | | | | | | | |
| Example | P2 | 100 | 50 | 30 | — | — | — | — | A | B | C |
| 109 | | | | | | | | | | | |
| Example | P2 | 100 | 50 | 30 | — | — | — | — | A | B | B |
| 110 | | | | | | | | | | | |
| Example | P2 | 100 | 50 | 30 | P1 | 100 | 0.5 + 0.5 | | A | A | B |
| 111 | | | | | | | | | | | |
| Example | P2 | 100 | 50 | 30 | P1 | 100 | 0.5 + 0.5 | | A | A | A |
| 112 | | | | | | | | | | | |
| Example | P2 | 100 | 50 | 30 | P1 | 100 | 1 + 1 | | B | A | A |
| 113 | | | | | | | | | | | |
| Example | P2 | 100 | 50 | 30 | P1 | 100 | 1 + 1 | | B | A | A |
| 114 | | | | | | | | | | | |
| Example | P3 | 100 | 50 | 30 | — | — | — | — | A | B | C |
| 115 | | | | | | | | | | | |
| Example | P3 | 100 | 50 | 30 | — | — | — | — | A | B | B |
| 116 | | | | | | | | | | | |
| Example | P3 | 100 | 50 | 30 | P1 | 100 | 0.5 + 0.5 | | A | A | B |
| 117 | | | | | | | | | | | |
| Example | P3 | 100 | 50 | 30 | P1 | 100 | 0.5 + 0.5 | | A | A | A |
| 118 | | | | | | | | | | | |
| Example | P3 | 100 | 50 | 30 | P1 | 100 | 1 + 1 | | B | A | A |
| 119 | | | | | | | | | | | |
| Example | P3 | 100 | 50 | 30 | P1 | 100 | 1 + 1 | | B | A | A |
| 120 | | | | | | | | | | | |
| Example | P2 + K1 | 100 | 50 | 30 | — | — | — | — | A | B | C |
| 121 | | | | | | | | | | | |
| Example | P2 + K1 | 100 | 50 | 30 | — | — | — | — | A | B | B |
| 122 | | | | | | | | | | | |
| Example | P2 + K1 | 100 | 50 | 30 | P1 | 100 | 0.5 + 0.5 | | A | A | B |
| 123 | | | | | | | | | | | |
| Example | P2 + K1 | 100 | 50 | 30 | P1 | 100 | 0.5 + 0.5 | | A | A | A |
| 124 | | | | | | | | | | | |
| Example | P2 + K1 | 100 | 50 | 30 | P1 | 100 | 1 + 1 | | B | A | A |
| 125 | | | | | | | | | | | |
| Example | P2 + K1 | 100 | 50 | 30 | P1 | 100 | 1 + 1 | | B | A | A |
| 126 | | | | | | | | | | | |

As shown in Table 11, it was found that the films of Examples 103 to 126 included an a high permittivity and a low dielectric loss tangent.

### Examples 201 to 224

Details of each material used for producing the laminated film are as follows. The same materials as in Example 1A and the like are omitted.

### <Resin>

P5: Styrene-ethylene-butylene-styrene block copolymer, product name “TUFTEC M1913”, manufactured by Asahi Kasei Corporation

### Layer A and Layer B-

The layer A and the layer B were formed by the same method as in Example 1A.

### Layer C-

The layer C was formed on one surface of the layer A and the layer B by the same method as in Example 9.

As a result, the copper foil M1, “the layer A and the layer B”, and the layer C were formed in this order.

Next, the copper foil M1 was etched and removed with ferric chloride. With this, the film consisting of “the layer A and the layer B” and the layer C was formed.

### -Laminated Film-

The film consisting of “the layer A and the layer B” and the layer C was laminated as many as shown in Table 12, and the laminated film was subjected to a heat press for 1 hour under the conditions of 160° C. and 4 MPa to obtain a laminated film.

TABLE 12

| | Laminated Film | | | | | | | | | Layer A | | | | | |
|---|---|---|---|---|---|---|---|---|---|---|---|---|---|---|---|
| | Resin | | Inorganic filler | | Copper | Thick- | Surface | | Number | Resin | | Inorganic filler | | | Thick- |
| | | % by | | % by | foil | ness | roughness | Do/ | of lami- | | % by | | % by | Width | ness |
| | Type | volume | Type | volume | Type | μm | μm | Di | nation | Type | volume | Type | volume | μm | μm |
| Example | P1 | 40 | F2 | 60 | M1 | 100 | 1 | 0.7 | 3 | P1 | 10 | F2 | 90 | 300 | 30 |
| 201 | | | | | | | | | | | | | | | |
| Example | P1 | 50 | F2 | 50 | M1 | 100 | 1 | 0.7 | 3 | P1 | 20 | F2 | 80 | 300 | 30 |
| 202 | | | | | | | | | | | | | | | |
| Example | P1 | 55 | F2 | 45 | M1 | 100 | 1 | 0.7 | 3 | P1 | 30 | F2 | 70 | 300 | 30 |
| 203 | | | | | | | | | | | | | | | |
| Example | P1 | 40 | F2 | 50 | M1 | 500 | 1 | 0.7 | 16 | P1 | 10 | F2 | 90 | 300 | 30 |
| 204 | | | | | | | | | | | | | | | |
| Example | P1 | 50 | F2 | 50 | M1 | 500 | 1 | 0.7 | 16 | P1 | 20 | F2 | 80 | 300 | 30 |
| 205 | | | | | | | | | | | | | | | |
| Example | P1 | 55 | F2 | 45 | M1 | 500 | 1 | 0.7 | 16 | P1 | 30 | F2 | 70 | 300 | 30 |
| 206 | | | | | | | | | | | | | | | |
| Example | P1 + P2 | 40 | F2 | 50 | M1 | 100 | 1 | 0.7 | 3 | P1 | 10 | F2 | 90 | 300 | 30 |
| 207 | | | | | | | | | | | | | | | |
| Example | P1 + P2 | 50 | F2 | 50 | M1 | 100 | 1 | 0.7 | 3 | P1 | 20 | F2 | 80 | 300 | 30 |
| 208 | | | | | | | | | | | | | | | |
| Example | P1 + P2 | 55 | F2 | 45 | M1 | 100 | 1 | 0.7 | 3 | P1 | 30 | F2 | 70 | 300 | 30 |
| 209 | | | | | | | | | | | | | | | |
| Example | P1 + P2 | 40 | F2 | 50 | M1 | 500 | 1 | 0.7 | 16 | P1 | 10 | F2 | 90 | 300 | 30 |
| 210 | | | | | | | | | | | | | | | |
| Example | P1 + P2 | 50 | F2 | 50 | M1 | 500 | 1 | 0.7 | 16 | P1 | 20 | F2 | 80 | 300 | 30 |
| 211 | | | | | | | | | | | | | | | |
| Example | P1 + P2 | 55 | F2 | 45 | M1 | 500 | 1 | 0.7 | 16 | P1 | 30 | F2 | 70 | 300 | 30 |
| 212 | | | | | | | | | | | | | | | |
| Example | P1 + P3 | 40 | F2 | 60 | M1 | 100 | 1 | 0.7 | 3 | P1 | 10 | F2 | 90 | 300 | 30 |
| 213 | | | | | | | | | | | | | | | |
| Example | P1 + P3 | 50 | F2 | 50 | M1 | 100 | 1 | 0.7 | 3 | P1 | 20 | F2 | 80 | 300 | 30 |
| 214 | | | | | | | | | | | | | | | |
| Example | P1 + P3 | 55 | F2 | 45 | M1 | 100 | 1 | 0.7 | 3 | P1 | 30 | F2 | 70 | 300 | 30 |
| 215 | | | | | | | | | | | | | | | |
| Example | P1 + P3 | 40 | F2 | 60 | M1 | 500 | 1 | 0.7 | 16 | P1 | 10 | F2 | 90 | 300 | 30 |
| 216 | | | | | | | | | | | | | | | |
| Example | P1 + P3 | 50 | F2 | 50 | M1 | 500 | 1 | 0.7 | 16 | P1 | 20 | F2 | 80 | 300 | 30 |
| 217 | | | | | | | | | | | | | | | |
| Example | P1 + P3 | 55 | F2 | 45 | M1 | 500 | 1 | 0.7 | 16 | P1 | 30 | F2 | 70 | 300 | 30 |
| 218 | | | | | | | | | | | | | | | |
| Example | P1 + | 40 | F2 | 60 | M1 | 100 | 1 | 0.7 | 3 | P1 | 10 | F2 | 90 | 300 | 30 |
| 219 | P2 + K1 | | | | | | | | | | | | | | |
| Example | P1 + | 50 | F2 | 50 | M1 | 100 | 1 | 0.7 | 3 | P1 | 20 | F2 | 80 | 300 | 30 |
| 220 | P2 + K1 | | | | | | | | | | | | | | |
| Example | P1 + | 55 | F2 | 45 | M1 | 100 | 1 | 0.7 | 3 | P1 | 30 | F2 | 70 | 300 | 30 |
| 221 | P2 + K1 | | | | | | | | | | | | | | |
| Example | P1 + | 40 | F2 | 60 | M1 | 500 | 1 | 0.7 | 16 | P1 | 10 | F2 | 90 | 300 | 30 |
| 222 | P2 + K1 | | | | | | | | | | | | | | |
| Example | P1 + | 50 | F2 | 50 | M1 | 500 | 1 | 0.7 | 16 | P1 | 20 | F2 | 80 | 300 | 30 |
| 223 | P2 + K1 | | | | | | | | | | | | | | |
| Example | P1 + | 55 | F2 | 45 | M1 | 500 | 1 | 0.7 | 16 | P1 | 30 | F2 | 70 | 300 | 30 |
| 224 | P2 + K1 | | | | | | | | | | | | | | |

| | Layer B | | | | Layer C | | | | | |
|---|---|---|---|---|---|---|---|---|---|---|
| | Resin | | | | Resin | | | Evaluation | | |
| | | % by | Width | Thickness | | % by | Thickness | Relative | | Transmission |
| | Type | volume | μm | μm | Type | volume | μm | permittivity | Brittleness | loss |
| Example | P1 | 100 | 50 | 30 | P5 | 100 | 1 | A | B | A |
| 201 | | | | | | | | | | |
| Example | P1 | 100 | 50 | 30 | P5 | 100 | 1 | A | B | A |
| 202 | | | | | | | | | | |
| Example | P1 | 100 | 50 | 30 | P5 | 100 | 1 | B | A | A |
| 203 | | | | | | | | | | |
| Example | P1 | 100 | 50 | 30 | P5 | 100 | 1 | A | B | A |
| 204 | | | | | | | | | | |
| Example | P1 | 100 | 50 | 30 | P5 | 100 | 1 | A | B | A |
| 205 | | | | | | | | | | |
| Example | P1 | 100 | 50 | 30 | P5 | 100 | 1 | B | A | A |
| 206 | | | | | | | | | | |
| Example | P2 | 100 | 50 | 30 | P5 | 100 | 1 | A | B | A |
| 207 | | | | | | | | | | |
| Example | P2 | 100 | 50 | 30 | P5 | 100 | 1 | A | B | A |
| 208 | | | | | | | | | | |
| Example | P2 | 100 | 50 | 30 | P5 | 100 | 1 | B | A | A |
| 209 | | | | | | | | | | |
| Example | P2 | 100 | 50 | 30 | P5 | 100 | 1 | A | B | A |
| 210 | | | | | | | | | | |
| Example | P2 | 100 | 50 | 30 | P5 | 100 | 1 | A | B | A |
| 211 | | | | | | | | | | |
| Example | P2 | 100 | 50 | 30 | P5 | 100 | 1 | B | A | A |
| 212 | | | | | | | | | | |
| Example | P3 | 100 | 50 | 30 | P5 | 100 | 1 | A | B | A |
| 213 | | | | | | | | | | |
| Example | P3 | 100 | 50 | 30 | P5 | 100 | 1 | A | B | A |
| 214 | | | | | | | | | | |
| Example | P3 | 100 | 50 | 30 | P5 | 100 | 1 | B | A | A |
| 215 | | | | | | | | | | |
| Example | P3 | 100 | 50 | 30 | P5 | 100 | 1 | A | B | A |
| 216 | | | | | | | | | | |
| Example | P3 | 100 | 50 | 30 | P5 | 100 | 1 | A | B | A |
| 217 | | | | | | | | | | |
| Example | P3 | 100 | 50 | 30 | P5 | 100 | 1 | B | A | A |
| 218 | | | | | | | | | | |
| Example | P2 + K1 | 100 | 50 | 30 | P5 | 100 | 1 | A | B | A |
| 219 | | | | | | | | | | |
| Example | P2 + K1 | 100 | 50 | 30 | P5 | 100 | 1 | A | B | A |
| 220 | | | | | | | | | | |
| Example | P2 + K1 | 100 | 50 | 30 | P5 | 100 | 1 | B | A | A |
| 221 | | | | | | | | | | |
| Example | P2 + K1 | 100 | 50 | 30 | P5 | 100 | 1 | A | B | A |
| 222 | | | | | | | | | | |
| Example | P2 + K1 | 100 | 50 | 30 | P5 | 100 | 1 | A | B | A |
| 223 | | | | | | | | | | |
| Example | P2 + K1 | 100 | 50 | 30 | P5 | 100 | 1 | B | A | A |
| 224 | | | | | | | | | | |

As shown in Table 12, it was found that the laminated films of Examples 201 to 224 included a film including an inorganic filler and a resin, and had a ratio (Do/Di) of 0.5 or more, and thus could achieve both a high permittivity and a low dielectric loss tangent.

The disclosure of Japanese Patent Application No. 2023-118688 filed on Jul. 20, 2023, Japanese Patent Application No. 2023-187213 filed on Oct. 31, 2023, Japanese Patent Application No. 2023-207955 filed on Dec. 8, 2023, and Japanese Patent Application No. 2024-029091 filed on Feb. 28, 2024 are incorporated in the present specification by reference. In addition, all documents, patent applications, and technical standards described in the present specification are incorporated herein by reference to the same extent as in a case of being specifically and individually noted that individual documents, patent applications, and technical standards are incorporated by reference.

What is claimed is:

1. A film comprising:
a filler; and
a resin,
wherein the filler is at least one selected from the group consisting of an inorganic filler and an organic filler, and
a ratio (Do/Di) of a number (Do) of particles of the filler per unit area in a thickness direction to a number (Di) of particles of the filler per unit area in an in-plane direction is 0.5 or more.

2. The film according to claim 1,
wherein the film comprises the inorganic filler and the resin.

3. The film according to claim 2,
wherein a relative permittivity of the inorganic filler is 1 to 20,000.

4. The film according to claim 2,
wherein a relative permittivity of the inorganic filler is 6 to 20,000.

5. The film according to claim 2,
wherein the inorganic filler comprises at least one selected from the group consisting of barium titanate, strontium titanate, calcium titanate, magnesium titanate, bismuth titanate, zirconium titanate, zinc titanate, titanium dioxide, magnesium oxide, alumina, tantalum pentoxide, and niobium pentoxide.

6. The film according to claim 1,
wherein the film comprises the organic filler and the resin.

7. The film according to claim 1,
wherein a relative permittivity of the filler is 1 to 6.

8. The film according to claim 1,
wherein an average particle diameter of the filler is 0.01 μm to 10 μm.

9. The film according to claim 1,
wherein a content of the filler is 1% by volume to 95% by volume with respect to a total amount of the film.

10. The film according to claim 1,
wherein the resin comprises at least one selected from the group consisting of a thermoplastic resin, a thermoplastic elastomer, a semi-cured product of a thermosetting resin, a semi-cured product of a photocurable resin, a cured product of the thermosetting resin, a cured product of a photocurable resin, a semi-cured product of a thermosetting elastomer, a semi-cured product of a photocurable elastomer, a cured product of the thermosetting elastomer, and a cured product of the photocurable elastomer.

11. The film according to claim 10, wherein:
the thermosetting resin or the photocurable resin is an epoxy resin; and
the film further comprises an active ester compound as a curing agent.

12. The film according to claim 1, wherein:
the film comprises a plurality of layers A comprising 50% by volume or more of the filler, and a layer B comprising the resin; and
the plurality of layers A and the layer B are disposed in the same plane, and the plurality of layers A are disposed so as not to be in contact with each other.

13. The film according to claim 12, wherein:
the film comprises a resin layer C; and
the resin layer C is in contact with the layers A and the layer B.

14. The film according to claim 1, having a surface roughness of 5 μm or less.

15. A laminated film comprising a plurality of films according to claim 1 stacked such that the films are in contact with each other.

16. A laminated plate comprising:
the film according to claim 1; and
a metal layer or a metal pattern disposed on at least one surface of the film.

17. A printed wiring board comprising the laminated plate according to claim 16.

18. An antenna substrate comprising the laminated plate according to claim 16.

19. An antenna module comprising the antenna substrate according to claim 18,
wherein the antenna module is configured to perform at least one of transmission or reception of radio waves having a frequency of 6 to 24 GHz.

20. An antenna module comprising the antenna substrate according to claim 18,
wherein the antenna module is configured to perform at least one of transmission or reception of radio waves having a frequency of 0.5 to 5.9 GHz.

21. A metamaterial comprising a pattern provided on at least one surface of the film according to claim 1,
wherein the pattern is composed of at least one selected from the group consisting of a conductive material and a material that changes from an insulator to a conductor.

22. An electromagnetic wave absorbing film comprising:
the metamaterial according to claim 21.
